(19) United States
(12) Patent Application Publication
(10) Pub. No.: US 2026/0331622 A1
(43) Pub. Date: Oct. 22, 2026

(54) THERMAL MANAGEMENT SYSTEM FOR VEHICLE

(71) Applicant: Zoox, Inc., Foster City, CA (US)

(72) Inventors: Paul Raymond Mueller, San Leandro, CA (US); Srinivasa Rao Vaddiraju, Fremont, CA (US)

(21) Appl. No.: 19/184,820

(22) Filed: Apr. 21, 2025

(51) Int. Cl. H01M 10/633; G06F 1/20; H01M 10/48; H01M 10/613; H01M 10/625; H01M 10/6569; H01M 10/66; H05K 7/20; B60L 58/26

(52) U.S. Cl. CPC H01M 10/633; G06F 1/206; H01M 10/482; H01M 10/486; H01M 10/613; H01M 10/625; H01M 10/6569; H01M 10/66; H05K 7/20263; H05K 7/20281; B60L 58/26; B60L 2240/545; H01M 2220/20

(57) ABSTRACT

A thermal management system for a vehicle includes a radiator and a chiller. The thermal management system may include multiple configurations to provide cooling to components of the vehicle. In a first configuration, the components may be cooled via a radiator. In a second configuration, some of the components may be cooled via the radiator while other components may be cooled via a chiller. In a third configuration, the components may be cooled via the chiller. The configuration of the thermal management system may be based on the temperature of the components.

### BACKGROUND

A vehicle may include computing components that permit operation of the vehicle. In the case of autonomous vehicles, the computing components may be responsible for controlling the vehicle within an environment. In addition, the vehicle may include one or more batteries for supplying power to the computing components, and/or other components of the vehicle, such as motors, instrumentation, and/or lighting. The computing components, batteries, etc., generate heat during operation. If the heat is not effectively dissipated or otherwise controlled, operation of the vehicle may be adversely impacted.

### BRIEF DESCRIPTION OF THE DRAWINGS

The Detailed Description is set forth with reference to the accompanying figures. In the figures, the left-most digit(s) of a reference number identifies the figure in which the reference number first appears. The use of the same reference numbers in different figures indicates similar or identical items. Furthermore, the drawings may be considered as providing an approximate depiction of the relative sizes of the individual components within individual figures. However, the drawings are not to scale, and the relative sizes of the individual components, both within individual figures and between the different figures, may vary from what is depicted.

FIG. 1 illustrates a diagram showing an example thermal management system for providing cooling to components of a vehicle, according to an embodiment of the present disclosure.

FIG. 2 illustrates an example first configuration of the thermal management system of FIG. 1, according to an embodiment of the present disclosure.

FIG. 3 illustrates an example second configuration of the thermal management system of FIG. 1, according to an embodiment of the present disclosure.

FIG. 4 illustrates an example third configuration of the thermal management system of FIG. 1, according to an embodiment of the present disclosure.

FIG. 5A illustrates an alternative example of a thermal management system for providing cooling to components of the vehicle of FIG. 1, according to an embodiment of the present disclosure.

FIG. 5B illustrates an alternative example of a thermal management system for providing cooling to components of the vehicle of FIG. 1, according to an embodiment of the present disclosure.

FIG. 6 is a block diagram of an example system for implementing the techniques described herein, according to an embodiment of the present disclosure.

FIG. 7 illustrates an example process for providing cooling to components of a vehicle, according to an embodiment of the present disclosure.

FIG. 8 illustrates an example process for providing cooling to components of a vehicle, according to an embodiment of the present disclosure.

FIG. 9 illustrates an example process for providing cooling to components of a vehicle, according to an embodiment of the present disclosure.

### DETAILED DESCRIPTION

This patent application is directed, at least in part, to a thermal management system of a vehicle, according to an embodiment of the present disclosure. In an embodiment, the thermal management system may include multiple loops, configurations, components, etc., to provide cooling to components of the vehicle. For example, the vehicle may include computing components (e.g., GPUs, CPUs, hardware, etc.) and/or batteries that need cooling. The computing components and/or the batteries may need to be cooled to certain temperatures to permit their operation and/or prevent damage. In an embodiment, the configuration of the thermal management system may be dependent on the temperature of the computing components, the batteries, an environment of the vehicle, etc. For example, based on the temperature of the computing components and the batteries, the thermal management system may operate at a certain configuration. The different configurations of the thermal management system may reduce wear on components of the thermal management system, reduce an energy consumption, and/or effectively cool the computing components and the batteries.

In an embodiment, the thermal management system may include three configurations. The three configurations may utilize different components, cycles, loops, etc., of the thermal management system to cool the computing components and the batteries. In an embodiment, depending upon the configuration of the thermal management system that provides cooling to the computing components and the batteries, some of the components of the thermal management system may be utilized while other components may not be utilized. A controller of the thermal management system, for example, may control various valves, junctions, pumps, etc., to control a flow of coolant throughout the thermal management system to provide cooling to the computing components and the batteries based on the configuration.

In a first configuration, a radiator of the thermal management system may cool a coolant that provides cooling to the computing components and the batteries. In an embodiment, the thermal management system may operate according to the first configuration based at least in part on a temperature associated with the thermal management system being below a first temperature threshold. In an embodiment, the temperature of the thermal management system may be associated with a temperature of the coolant exiting the radiator, a temperature of the computing components, a temperature of the batteries, and/or a temperature of an environment of the vehicle (e.g., ambient temperature).

In an embodiment, the first temperature threshold may be 35°C, which is associated with a preferred or maximum operating temperature of the batteries. If the temperature of the coolant exiting the radiator, for example, is less than 35°C, the first configuration of the thermal management system may provide sufficient cooling to the batteries to operate at their preferred operating temperature or below their maximum operating temperature. The computing components, as discussed herein, may have a preferred operating temperature or maximum operating temperature of 55°C, which is higher than the preferred operating temperature of the batteries. As such, the preferred operating temperature of the batteries may be used as the first temperature threshold to configure the thermal management system according to the first configuration.

In the first configuration, a first pump may pump the coolant to the computing components and the batteries. In the first configuration, a first portion of the coolant may be routed to the computing components and a second portion of the coolant may be routed to the batteries. After passing through the computing components and the batteries, the first portion of the coolant and the second portion of the coolant may be combined and routed back to the radiator, whereby the radiator may transfer heat to the environment to cool the coolant. In an embodiment, the coolant may be provided to the computing components and the batteries in parallel.

The thermal management system may include one or more valves, junctions, hoses, lines, etc., that control a flow of the coolant to the computing components and the batteries, as well as from the computing components and the batteries to the radiator, in the first configuration. The controller of the thermal management system may control the valves, for example, to route the coolant according to the first configuration. Temperature sensors (e.g., thermocouples) may be disposed within the radiator, the computing components, the batteries, the hoses, etc., for measuring a temperature of the coolant, the computing components, and/or the batteries.

In a second configuration, the radiator of the thermal management system may cool a coolant to cool to the computing components. Additionally, in the second configuration, a chiller may cool a coolant to cool the batteries. In an embodiment, the thermal management system may operate according to the second configuration based at least in part on the temperature associated with the thermal management system being greater than the first temperature threshold but less than a second temperature threshold. In an embodiment, the temperature of the thermal management system to control the thermal management system according to the second configuration may be associated with a temperature of the coolant exiting the radiator, a temperature of a coolant exiting the chiller, a temperature of the computing components, a temperature of the batteries, or a temperature of the environment of the vehicle.

In an embodiment, the second temperature threshold may be 55°C, which is associated with a preferred operating temperature of the computing components. In other words, if the coolant exiting the radiator is less than 55°C, the second configuration of the thermal management system may provide sufficient cooling to the computing components to operate at their preferred operating temperature. However, the 55°C temperature of the coolant is higher than the preferred operating temperature of the batteries, meaning that the coolant flowing through the radiator is unable to provide sufficient cooling to the batteries. Accordingly, the chiller of the thermal management system may be used to provide cooling to the batteries.

In the second configuration, the radiator may be isolated from other components of the thermal management system. For example, valves that previously fluidly connected the radiator to the batteries (e.g., in the first configuration) may be adjusted such that the coolant flowing through the radiator is routed to the computing components. The controller of the thermal management system may control the valves to restrict the flow of the coolant from the radiator to the batteries.

To provide cooling to the batteries, the chiller may be fluidly connected to a condenser and a compressor. A refrigerant flowing through the chiller may exchange heat with the coolant routed to the batteries. The compressor may compress the refrigerant into a high-pressure, high-temperature gas. The high-pressure, high-temperature gas is then condensed in the condenser to a liquid state. During this phase change, the refrigerant becomes cooled by exchanging heat with the environment. A thermal expansion valve may be disposed between the condenser and the chiller to reduce a pressure of the refrigerant, and correspondingly, its temperature, before cooling the coolant within the chiller. Once routed to the chiller, the refrigerant cools the coolant flowing to the batteries.

In the second configuration, a second pump may pump the coolant from the chiller to the batteries. The coolant flowing through the chiller is separate from the coolant flowing through the radiator, thereby isolating a coolant loop associated with cooling the computing components from a coolant loop associated with cooling the batteries. For example, first coolant flowing through the radiator may be used to cool the computing components and second coolant flowing through the chiller may be used to cool the batteries. The first coolant and the second coolant may be the same, however, the first coolant and the second coolant may be isolated from one another. In the second configuration, the first coolant and the second coolant may not mix within the thermal management system. The first coolant may cycle through the radiator to be cooled and provide cooling to the computing components. In contrast, the second coolant may cycle through the chiller to be cooled (via the refrigerant) and provide cooling to the batteries.

In the second configuration, one or more valves, junctions, hoses, lines, etc., may control a flow of the coolant to the batteries, as well as from the batteries to the radiator. Temperature sensors (e.g., thermocouples) may be disposed within the batteries, hoses, etc., for measuring a temperature of the coolant and/or the batteries. Various valves, junctions, hoses, lines, etc., may control a flow of refrigerant through the chiller, the compressor, and the condenser. Moreover, temperature sensors may also measure a temperature of the refrigerant. The controller of the thermal management system may function to control the valves, etc., for operating the thermal management system according to the second configuration.

In the third configuration, the chiller of the thermal management system cools a coolant to cool to the computing components and the batteries. In an embodiment, the thermal management system may operate according to the third configuration based at least in part on the temperature associated with the thermal management system being greater than the second temperature threshold. In an embodiment, the temperature of the thermal management system used to control the thermal management system according to the third configuration may be associated with a temperature of the coolant exiting the radiator, a temperature of the coolant exiting the chiller, a temperature of the computing components, a temperature of the batteries, or a temperature of the environment of the vehicle. For example, on extreme temperature days or when the ambient temperature is above a temperature threshold, the chiller may provide cooling to the computing components and the batteries.

As introduced above, the second temperature threshold may be 55°C, which is associated with a preferred operating temperature of the computing components. In other words, if the coolant exiting the radiator is greater than 55°C, the coolant flowing through the radiator may be unable to provide sufficient cooling to the computing components (as well as the batteries). Accordingly, the chiller of the thermal management system may be used to provide cooling to the computing components and the batteries.

In the third configuration, the radiator may be isolated from other components of the thermal management system. That is, because the chiller provides cooling to both the computing components and the batteries, the radiator may be isolated (e.g., disconnected, separated, etc.) from the computing components and the batteries. For example, valves that previously fluidly connected the radiator to the computing components (e.g., in the second configuration) may be adjusted such that the radiator is isolated from the computing components and the batteries. The controller of the thermal management system may control the valves to isolate the radiator.

To provide cooling to the computing components and the batteries, the chiller may be fluidly connected to the computing components. This may include adjusting valves that once isolated the coolant (e.g., the first coolant) flowing through the computing components from the coolant (e.g., the second coolant) flowing through the batteries in the second configuration. Instead, a portion of the coolant flowing through the computing components during the first configuration and/or the second configuration may be combined with the coolant flowing through the batteries. Cooling the coolant flowing through the computing components and the batteries may come by way of the refrigerant, as similarly discussed above to cool the batteries in the second configuration. However, in the third configuration, the coolant may be cooled by greater amounts (e.g., the condenser may reject more heat to the environment, the compressor may perform more work, etc.) to cool the coolant and provide cooling to the computing components and the batteries.

In the third configuration of the thermal management system, the second pump may pump coolant to both the computing components and the batteries. A first portion of the coolant flowing through the chiller may be routed to the computing components and a second portion of the coolant flowing through the chiller may be routed to the batteries. In an embodiment, the coolant may be provided to the computing components and the batteries in parallel. After passing through the computing components and the batteries, the first portion of the coolant and the second portion of the coolant may be combined and routed back to the chiller, whereby the coolant may exchange heat with the refrigerant flowing through the chiller. In the third configuration, one or more valves, junctions, hoses, lines, etc., may control a flow of the coolant to the computing components and the batteries.

In an embodiment, the radiator may provide supplemental, or ancillary, cooling in the third configuration. For example, given that in the third configuration the condenser is required to cool the refrigerant to provide cooling for both the computing components and the batteries, in an effort to reduce a size of the condenser, coolant flowing through the radiator may be used to cool the refrigerant. In an embodiment, a liquid cooled condenser (LCC) may be fluidly connected to the condenser, the chiller, and the compressor. The LCC may also be fluidly connected to the radiator. The refrigerant may be cooled by a first amount within the condenser and may be cooled via a second amount within the LCC. Cooling of the refrigerant by the second amount by come by way of the coolant flowing through the radiator exchanging heat with the refrigerant within the LCC. In an embodiment, the refrigerant may be cooled within the LCC after passing through the condenser.

In an embodiment, a portion of the components of the thermal management system used to route the coolant to the radiator in the first configuration or the second configuration may be used to route the coolant from the radiator to the LCC in the third configuration. The controller of the thermal management system may be used to control the components for routing the coolant between the radiator and the LCC. In an embodiment, whether the radiator is used to provide supplemental cooling may be based at least in part on a temperature of the coolant exiting the chiller, an amount of work required by the compressor, an amount of heat required to be transferred via the condenser, a pressure differential across the chiller, and/or a pressure (e.g., greater than 2000 kPa) of the refrigerant exiting the compressor.

In an embodiment, in the third configuration, a portion of the coolant may bypass the chiller. For example, when the thermal management system changes from the second configuration to the third configuration, and mixing of the coolant occurs (e.g., 55°C from the radiator and 35°C from the batteries), the chiller may be incapable of providing sufficient cooling and/or the coolant may disturb the thermal management system (e.g., frost, condensation, etc.). Bypassing a portion of the coolant around the chiller may gradually cool the coolant. Once a certain percentage, portion, etc., of the coolant is bypassed, the bypass may be disabled and all of the coolant may be directed into the chiller to exchange heat with the refrigerant.

The radiator and/or the condenser may be located at a leading edge or a trailing edge of the vehicle. Fans disposed adjacent to the radiator and the condenser may provide cooling, for example, when the vehicle is stationary, when the vehicle is traveling at low rates of speed, and/or when the radiator and/or the condenser is located at a trailing edge of the vehicle. In an embodiment, the coolant may be a mixture of water and glycol. The refrigerant may be R1234yf.

In an embodiment, the controller may control the amount of coolant (or cooling) provided to the computing components and/or the batteries. The controller may control a position of the valves and/or a speed of the pumps, for example, to route different amounts of coolant to the computing components and the batteries or to cause different amounts of cooling to be provided to the computing components and/or the batteries. In an embodiment, the batteries may be more volatile or susceptible to damage from high temperatures. In certain applications, the controller may cause a greater amount of the coolant to be provided to the batteries as compared to the computing components. For example, on days were the ambient temperature is above a threshold, the controller may cause a greater amount of the coolant to be route to the batteries, whether in the first configuration, the second configuration, and/or the third configuration.

Although certain components of the thermal management system are described, the thermal management system may include additional or alternative components. For example, other radiators located about the vehicle may be used to cool the refrigerant and/or the coolant. Moreover, although described as providing cooling to the computing components and the batteries, the thermal management system may provide cooling to additional or alternative components of the vehicle. For example, drive systems, such as electric motors, may require cooling. The thermal management system may also be used in applications that exclude a vehicle. The thermal management system may also include more than or less than three configurations, or sub-configurations, to provide cooling.

The present disclosure provides an overall understanding of the principles of the structure, function, device, and system disclosed herein. One or more examples of the present disclosure are illustrated in the accompanying drawings. Those of ordinary skill in the art will understand and appreciate that the devices, the systems, and/or the methods specifically described herein and illustrated in the accompanying drawings are non-limiting embodiments. The features illustrated or described in connection with one embodiment or instance may be combined with the features of other embodiments or instances. Such modifications and variations are intended to be included within the scope of the disclosure and appended claims.

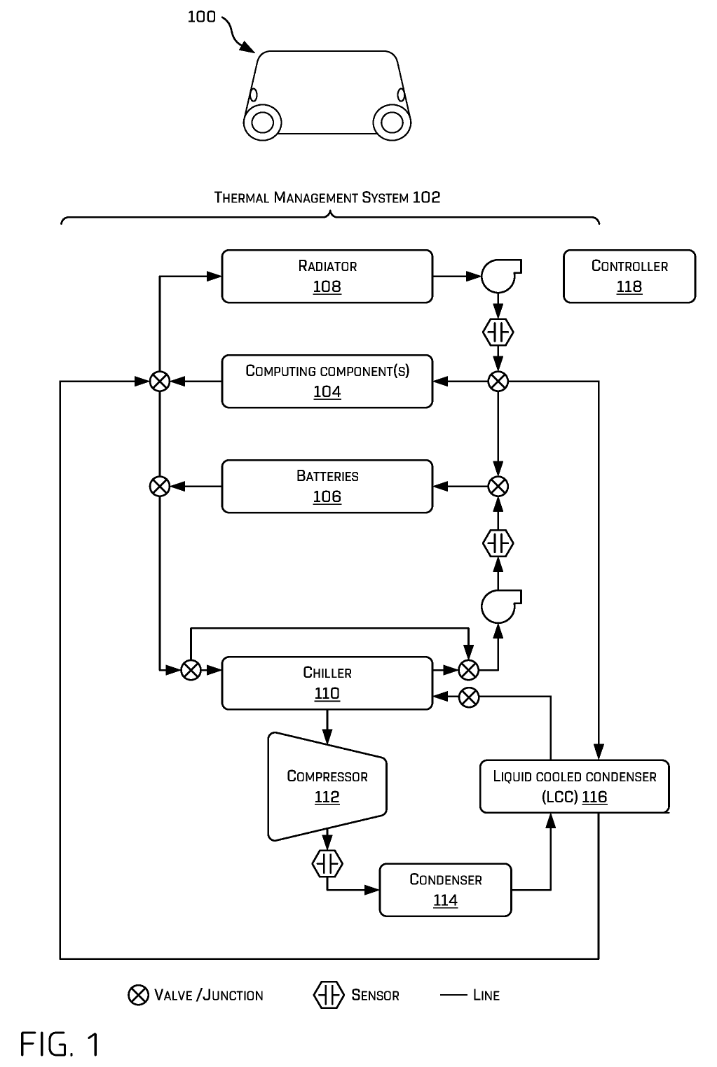

FIG. 1 illustrates an example vehicle 100 having a thermal management system 102, according to an embodiment of the present disclosure. In an embodiment, the vehicle 100 may be a driverless vehicle, such as an autonomous vehicle configured to operate according to a Level 5 classification issued by the U.S. National Highway Traffic Safety Administration, which describes a vehicle capable of performing all safety-critical functions for the entire trip, with the driver (or occupant) not being expected to control the vehicle 100 at any time. In such examples, because the vehicle 100 may be configured to control all functions from start to completion of the trip, including all parking functions, it may not include a driver and/or controls for driving the vehicle 100, such as a steering wheel, an acceleration pedal, and/or a brake pedal. This is merely an example, and the systems and methods described herein may be incorporated into any ground-borne, airborne, or waterborne vehicle, including those ranging from vehicles that need to be manually controlled by a driver at all times, to those that are partially- or fully-autonomously controlled.

The thermal management system 102 may include any number of components for providing cooling to computing components 104 and/or batteries 106 of the vehicle 100. The computing components 104 may be associated with controlling various operations of the vehicle 100. The batteries 106 may be responsible for powering components of the vehicle 100, such as the computing components 104. The computing components 104 and the batteries 106 require cooling to permit their operation, prevent overheating, and/or damage

The thermal management system 102 may include a radiator 108, a chiller 110, a compressor 112, a condenser 114, and a liquid cooled condenser (LCC) 116. In addition, the thermal management system 102 may include any number of valves (e.g., solenoid valves, 3-way valves, etc.), junctions (e.g., T junction), fittings, sensors (e.g., temperature, pressure, humidity, etc.), lines (e.g., hoses, pipes, conduit, etc.), fans (e.g., adjacent to radiator, condenser, etc.), etc. The thermal management system 102 may also include a controller 118 that at least partially performs operations associated with the thermal management system 102. As examples, the controller 118 may control settings of the valves, an operation of the compressor 112, etc. The controller 118 may communicate through wired connections or wireless with the components of the thermal management system 102.

Different components of the thermal management system 102 are configured to provide cooling to the computing components 104 and the batteries 106. In an embodiment, the configuration of the thermal management system 102, or which components of the thermal management system 102 provide cooling to the computing components 104 and the batteries 106, may be dependent upon temperatures within the thermal management system 102, a temperature of an environment of the vehicle 100, operating conditions of the computing components 104 and/or the batteries 106, and so forth.

In an embodiment, the thermal management system 102 may configure, or operate, according to different configurations. In a first configuration, the radiator 108 may provide cooling to the computing components 104 and the batteries 106. For example, a coolant flowing through the radiator may be supplied to the computing components 104 and the batteries 106 to provide cooling. In an embodiment, a first pump may supply the coolant to the computing components 104 and the batteries 106. After routing through the computing components 104 and the batteries 106, the coolant may be resupplied to the radiator 108. Valves disposed along lines, junctions, etc., between the radiator 108, the computing components 104, the batteries 106 may direct the flow of the coolant. As shown, the computing components 104 and the batteries 106 may be cooled in parallel.

In an embodiment, the thermal management system 102 may operate at the first configuration based at least in part on a temperature associated with the thermal management system 102. The temperature, for example, may be a temperature of the coolant exiting the radiator 108, a temperature of the computing components 104, a temperature of the batteries 106, a temperature of an environment, etc. If the temperature is less than a first temperature threshold (e.g., 35°C) the thermal management system 102 may operate at the first configuration. In the first configuration, the radiator 108, the computing components 104, and the batteries 106 are isolated from the remaining portions of the thermal management system 102, such as the chiller 110. The controller 118 may control respective portions of the thermal management system 102 (e.g., pumps, valves, etc.) to operate at the first configuration.

In a second configuration, the radiator 108 may provide cooling to the computing components 104 and the chiller 110 may provide cooling to the batteries 106. In an embodiment, the thermal management system 102 may operate at a second configuration based at least in part on a temperature associated with the thermal management system 102. The temperature, for example, may be a temperature of the coolant exiting the radiator 108, a temperature of the computing components 104, a temperature of the batteries 106, a temperature of an environment, a temperature of a coolant existing the chiller 110, etc. If the temperature is greater than the first temperature threshold but less than a second temperature threshold (e.g., 55°C), the thermal management system 102 may operate at the second configuration. In the second configuration, the coolant may flow through the radiator 108 to provide cooling to the computing components 104, as similarly discussed above with regard to the first configuration. However, the valves of the thermal management system 102 may be controlled such that coolant flowing through the radiator 108 is isolated from coolant flowing through the batteries 106, which is cooled via coolant flowing through the chiller 110. In other words, the radiator 108 may be fluidly isolated from other components of the thermal management system 102, such as the chiller 110.

The coolant flowing through the chiller 110 may be cooled via the condenser 114. For example, the compressor 112 may compress a refrigerant to a high-pressure, high-temperature gas. The high-pressure, high-temperature gas condenses in the condenser 114 to become a cooled liquid. A thermal expansion valve may be disposed between the condenser 114 and the chiller 110 to reduce a pressure of the refrigerant, and correspondingly, its temperature, before cooling the coolant flowing through the chiller 110. Within the chiller 110, the coolant transfers heat to the refrigerant. A pump may control a supply of the coolant to the batteries 106.

In the second configuration, the computing components 104 may be independently cooled from the batteries 106. The computing components 104 may be cooled via first components of the thermal management system 102, while the batteries 106 may be cooled via second components of the thermal management system 102.

In a third configuration, the chiller 110 provides cooling to both the computing components 104 and the batteries 106. In an embodiment, the thermal management system 102 may operate at the third configuration based at least in part on a temperature associated with the thermal management system 102. The temperature, for example, may be a temperature of the coolant exiting the radiator 108, a temperature of the computing components 104, a temperature of the batteries 106, a temperature of an environment, etc. If the temperature is greater than the second temperature threshold (e.g., 55°C) the thermal management system 102 may operate at the third configuration. In the third configuration, the radiator 108 may be isolated from the remaining components of the thermal management system 102. For example, valves may restrict a flow of the coolant flowing through the radiator 108 to be routed to the computing components 104 and the batteries 106. Instead, coolant flowing through the chiller 110 may be routed to both the computing components 104 and the batteries 106.

To provide cooling to the computing components 104 and the batteries 106, from the second configuration to the third configuration, the chiller 110 may be fluidly connected to the computing components. This may include adjusting valves that once isolated the coolant flowing through the computing components 104 from the coolant flowing through the batteries 106 in the second configuration. The controller 118 may control any number of the valves, junctions, etc., for routing the coolant flowing through the chiller 110 to the computing components 104 and the batteries 106.

Cooling the coolant flowing through the computing components 104 and the batteries 106 may come by way of the refrigerant, as similarly discussed above to cool the batteries 106 in the second configuration. In an embodiment, the coolant may be provided to the computing components 104 and the batteries 106 in parallel. After passing through the computing components 104 and the batteries 106, the coolant may be combined and routed back to the chiller 110, whereby the coolant may exchange heat with the refrigerant flowing through the chiller 110.

In an embodiment, in the third configuration, the radiator 108 may provide supplemental cooling. For example, in an effort to reduce a size of the condenser 114, the radiator 108 may be used to cool the refrigerant. In an embodiment, the LCC 116 may be fluidly connected to the radiator 108. The refrigerant may be cooled after passing through the condenser 114 via by a first amount within the condenser 114 and may be cooled via a second amount within the LCC 116. Cooling of the refrigerant by the second amount by come by way of the coolant exchanging heat with the refrigerant within the LCC 116. The coolant flowing through the LCC 116 may be cooled via the radiator 108. In an embodiment, the refrigerant may be cooled within the LCC 116 after passing through the condenser 114.

In an embodiment, whether the radiator 108 is used to provide supplemental cooling may be based at least in part on a temperature of the coolant exiting the chiller 110, an amount of work required by the compressor 112, an amount of heat required to be transferred via the condenser 114, a temperature differential across the chiller 110, and/or a pressure (e.g., greater than 2000 kPa) of the refrigerant exiting the compressor 112.

The radiator 108 and/or the condenser 114 may be located at a leading edge or a trailing edge of the vehicle 100. Fans disposed adjacent to the radiator 108 and the condenser 114 may provide cooling, for example, when the vehicle 100 is stationary, when the vehicle 100 is traveling at low rates of speed, and/or when the radiator 108 and/or the condenser 114 is located at a trailing edge of the vehicle 100.

Although certain components of the thermal management system 102 are described, the thermal management system 102 may include additional or alternative components. Details of the first configuration, the second configuration, and the third configuration of the thermal management system 102 are discussed herein. Moreover, in an embodiment, heat rejected by the radiator 108 and/or the condenser 114 may be used to heat components of the vehicle 100, such as a cabin of the vehicle 100 in which occupants reside.

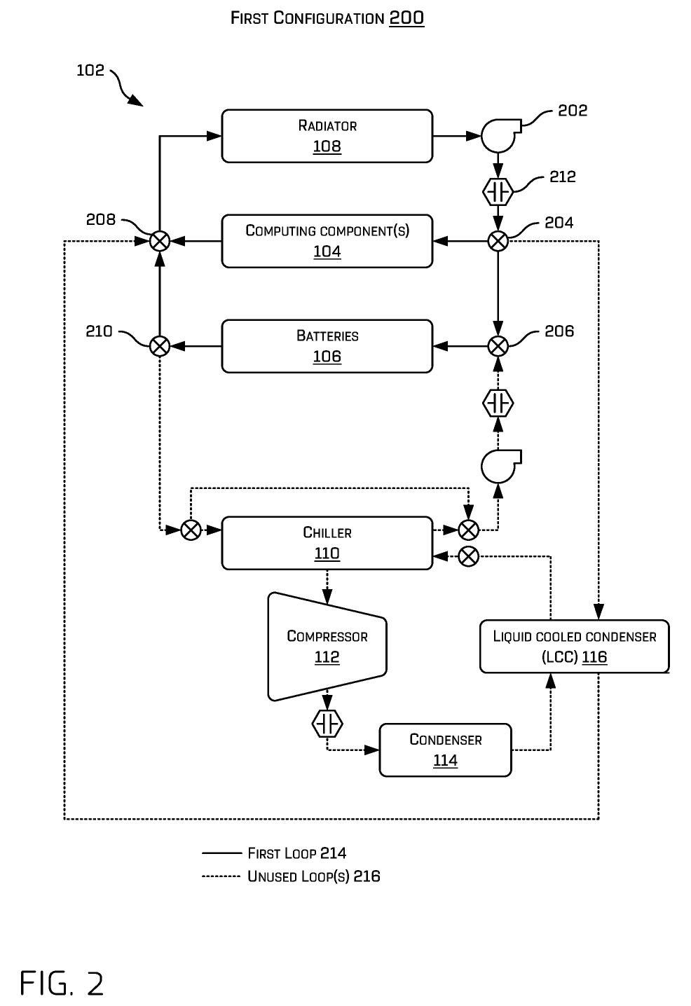

FIG. 2 illustrates a first configuration 200 of the thermal management system 102, according to an embodiment of the present disclosure. As introduced above, in the first configuration 200, the radiator 108 is utilized to provide cooling to the computing components 104 and the batteries 106. A pump 202, a first valve 204, a second valve 206, a third valve 208, and a fourth valve 210 of the thermal management system 102 may be responsible for routing the coolant from the radiator 108 to the computing components 104 and the batteries 106. For example, coolant may be pumped via the pump 202 to the first valve 204, whereby a first portion of the coolant may be directed to the computing components 104. The first valve 204 may also direct a second portion of the coolant to the second valve 206, which supplies the second portion of the coolant to the batteries 106. After the first portion of the coolant passes through the computing components 104, the third valve 208 may direct the first portion of the coolant back to the radiator 108. Moreover, after the second portion of the coolant passes through the batteries 106, the fourth valve 210 may direct the second portion of the coolant back to the radiator 108. During this, the second portion of the coolant may mix with the first portion of the coolant via the third valve 208.

The thermal management system 102 may additionally include various hoses, lines, fittings, couplers, etc., for routing the coolant to and from the radiator 108. The controller 118 may control (e.g., actuate) settings of the pump 202, the first valve 204, the second valve 206, the third valve 208, and the fourth valve 210 to route the coolant according to the first configuration 200. The controller 118 may also control an amount of coolant supplied to the computing components 104 and the batteries 106, thereby controlling an amount of cooling. For example, the computing components 104 and the batteries 106 may require different levels of cooling. By adjusting the speed of the pump 202, a radiator fan adjacent to the radiator 108, the first valve 204, the second valve 206, etc., the controller 118 may variably adjust the amount of cooling. For example, the batteries 106 may be more volatile or susceptible to damage from high temperatures than the computing components 104. In certain applications, the controller 118 may cause a greater amount of the coolant (and therefore cooling capacity) to be provided to the batteries 106 than the computing components 104. Various sensors (e.g., temperature sensors, pressure sensors, flow rate sensors, etc.) may be disposed about the thermal management system 102 for use by the controller 118. For example, where the ambient temperature is greater than a certain threshold (e.g., 43°C), the controller 118 may cause the batteries 106 to be cooled via greater amounts than the computing components 104 by adjusting valve(s), a speed of the pump(s), etc.

In an embodiment, the thermal management system 102 may operate according to the first configuration 200 based at least in part on a temperature associated with the thermal management system 102. In an embodiment, the temperature associated with the thermal management system 102 may be a temperature of the coolant exiting the radiator 108. For example, a temperature sensor 212 may measure a temperature of the coolant exiting the radiator 108 (e.g., after the pump 202). The temperature sensor 212 may be connected to the controller 118. In an embodiment, if the temperature measured by the temperature sensor 212 is less than a temperature threshold, the controller 118 may configure the thermal management system 102 to the first configuration 200. In an embodiment, the temperature threshold may be 35°C. The temperature threshold of 35°C may be associated with a maximum temperature of the batteries 106. In other words, if the temperature of the coolant is at least 35°C, the coolant may sufficiently cool the batteries 106 according to their designed parameters and/or to avoid damages to the batteries 106. The computing components 104 may have a maximum temperature greater than 35°C, and therefore, if the radiator 108 is able to provide sufficient cooling to the batteries 106, the radiator 108 is also able to provide sufficient cooling to the computing components 104.

However, although described as measuring the temperature of the coolant exiting the radiator 108, other temperatures may be used and/or temperatures of other components may be used to configure the thermal management system 102 according to the first configuration 200. For example, a temperature of the computing components 104, a temperature of the batteries 106, an ambient temperature of the environment, a temperature of the coolant elsewhere in the first configuration 200 (e.g., after exiting the batteries 106), etc., may be used to configure the thermal management system 102 to the first configuration. Still, although the temperature threshold for the first configuration is described as being 35°C, other temperature thresholds may be used.

In the first configuration 200, components of the thermal management system 102 may be isolated from other components of the thermal management system 102. For example, the chiller 110, the condenser 114, etc., may not be utilized in the first configuration 200 to provide cooling to the computing components 104 and/or batteries 106. Here, the second valve 206 and the fourth valve 210, for example, may be controlled to prevent coolant flowing to the chiller 110, the condenser 114, etc. Moreover, the first valve 204 and the third valve 208 may be controlled to restrict a flow of the coolant to other portions of the thermal management system 102 (as will be discussed herein).

In an embodiment, the first configuration 200 may correspond to a first loop 214 of the thermal management system 102. The first loop 214 is shown in solid lines and indicates components of the thermal management system 102 being used. The first loop 214 may also correspond to where the coolant is permitted to flow for cooling the computing components 104 and the batteries 106. Comparatively, those components of the thermal management system 102 not being utilized may correspond to unused loop(s) 216, which are shown in broken lines, and/or where the coolant is restricting from flowing.

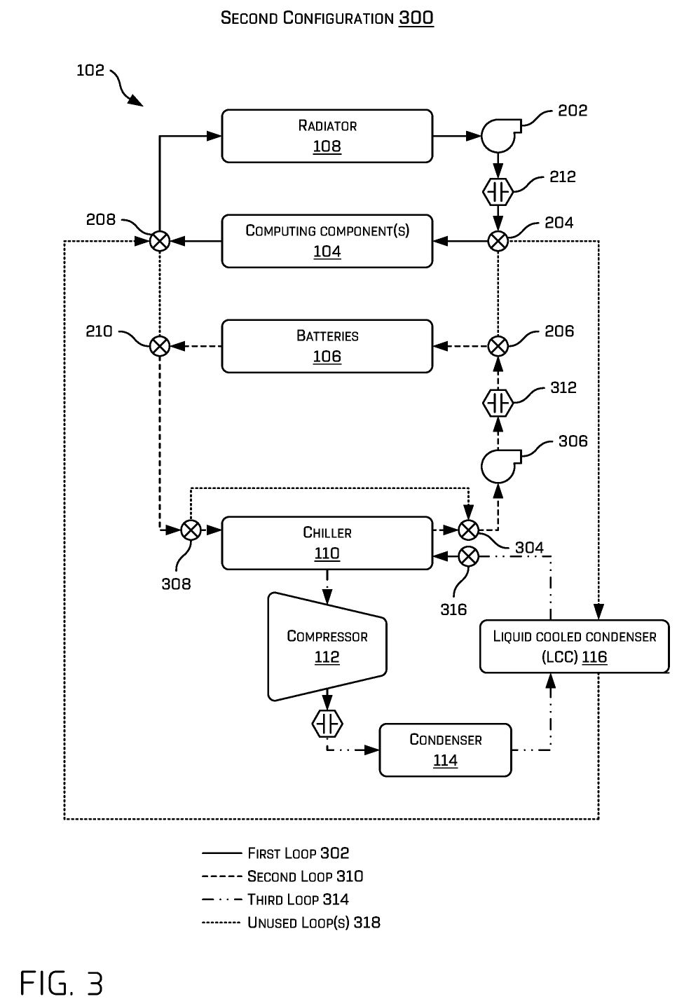

FIG. 3 illustrates a second configuration 300 of the thermal management system 102, according to an embodiment of the present disclosure. As introduced above, in the second configuration 300, the radiator 108 provides cooling to the computing components 104 and the chiller 110 provides cooling to the batteries 106.

The pump 202, the first valve 204, and the third valve 208 may be responsible for routing coolant to and from the radiator 108. For example, as similarly discussed above in FIG. 2 and the first configuration 200, the pump 202 may supply coolant to the first valve 204, which therein directs the coolant to the computing components 104. After exiting the computing components 104, the third valve 208 may then direct the coolant back to the radiator 108. In comparison to the first configuration 200, in the second configuration 300, the first valve 204 may restrict a flow of the coolant from the radiator 108 to the second valve 206. Coolant that is provided to the computing components 104 may be isolated from coolant provided to the batteries 106. A first loop 302 of the second configuration 300 may be between the radiator 108, the pump 202, the first valve 204, the computing components 104, and the third valve 208.

To cool the batteries 106, coolant may flow between the chiller 110, a fifth valve 304, a pump 306, the second valve 206, the fourth valve 210, and a sixth valve 308. This may correspond to a second loop 310 may correspond of the second configuration 300. The coolant flowing to the batteries 106 may be cooled within the chiller 110. More particularly, within the chiller 110, the coolant exchanges heat with a refrigerant. Upon exiting the chiller 110, the coolant may be pumped via the pump 306 to the second valve 206, which therein directs the coolant to the batteries 106. After exiting the batteries 106, the coolant may be directed by the fourth valve 210 back to the chiller 110.

The thermal management system 102 may include various hoses, lines, fittings, couplers, etc., for routing the coolant to and from the chiller 110. The thermal management system 102 also includes suitable components for routing the coolant to and from the radiator 108 (as discussed above). The controller 118 may control (e.g., actuate) settings of the pump 202, the pump 306, the first valve 204, the second valve 206, the third valve 208, the fourth valve 210, the fifth valve 304, and/or the sixth valve 308 to route the coolant according to the second configuration 300. The controller 118 may also control an amount of coolant supplied to the computing components 104 and the batteries 106, respectively, thereby controlling an amount of cooling. Moreover, various sensors (e.g., temperature sensors, pressure sensors, flow rate sensors, etc.) may be disposed about the thermal management system 102 for use by the controller 118. For example, a temperature sensor 312 may measure a temperature of the coolant on an outlet side of the chiller 110.

In an embodiment, the thermal management system 102 may operate according to the second configuration 300 based at least in part on a temperature associated with the thermal management system 102. In an embodiment, the temperature associated with the thermal management system 102 may be a temperature of the coolant exiting the radiator 108. For example, the temperature sensor 212 may measure a temperature of the coolant exiting the radiator 108. In an embodiment, if the temperature measured by the temperature sensor 212 is greater than the temperature threshold, the controller 118 may configure the thermal management system 102 to the second configuration 300. The temperature threshold may be 35°C. In addition, the controller 118 may configure the thermal management system 102 according to the second configuration 300 when the temperature of the coolant exiting the radiator 108 is less than a second temperature threshold. The second temperature threshold may be 55°C. The second temperature threshold of 55°C may be associated with a maximum temperature of the computing components 104. In other words, if the temperature of the coolant is at least 55°C, the coolant may sufficiently cool the computing components 104. However, the temperature of the coolant is insufficient to cool the batteries 106, which is why the thermal management system 102 enlists the second loop 310 (e.g., the chiller 110) to cool the batteries 106.

Although described as measuring the temperature of the coolant exiting the radiator 108, other temperatures may be used and/or temperatures of other components may be used to configure the thermal management system 102 according to the second configuration 300. For example, a temperature of the coolant exiting the chiller 110 may be used to configure the thermal management system 102 to the second configuration 300. Still, although the temperature threshold for the first configuration is described as being 55°C, other temperature thresholds may be used.

The refrigerant flowing through the chiller 110 may have a third loop 314. The third loop 314 may include the chiller 110, the compressor 112, the condenser 114, the LCC 116, and an eighth valve 316. Within the chiller 110, the refrigerant may cool the coolant, within the compressor 112, the refrigerant may be compressed, and within the condenser 114, the refrigerant may be cooled by rejecting heat to an environment. In the third loop 314, or the second configuration 300, the LCC 116 may be passive and the refrigerant may passively flow through the LCC 116. The eighth valve 316 may be a thermal expansion valve to reduce the temperature of the refrigerant before entering the chiller 110.

In the second configuration 300, components of the thermal management system 102 may be isolated from other components of the thermal management system 102. For example, the second valve 206 and the fourth valve 210 may isolate coolant flowing through the radiator 108 from coolant flowing through the chiller 110. In the second configuration 300, different components of the thermal management system 102 may provide cooling to the computing components 104 and the batteries 106.

The second configuration 300 of the thermal management system 102 may have unused components, or components that are isolated from components of the thermal management system 102 used to provide cooling in the second configuration 300. These components may include the LCC 116, whereby coolant is restricted from flowing through the LCC 116 via the first valve 204 and the second valve 206. Introduced above, in the second configuration 300, the LCC 116 may be passive because the refrigerant is not cooled within the LCC 116. Those components of the thermal management system 102 not being utilized may correspond to unused loop(s) 318, which are shown in broken lines, and/or where the coolant is not permitted to flow. Moreover, as will be discussed herein, in an embodiment, the fifth valve 304 and the sixth valve 308 may be used to bypass a portion of the coolant around the chiller 110. In the second configuration 300, however, the sixth valve 308 may not bypass coolant around the chiller 110 to the fifth valve 304.

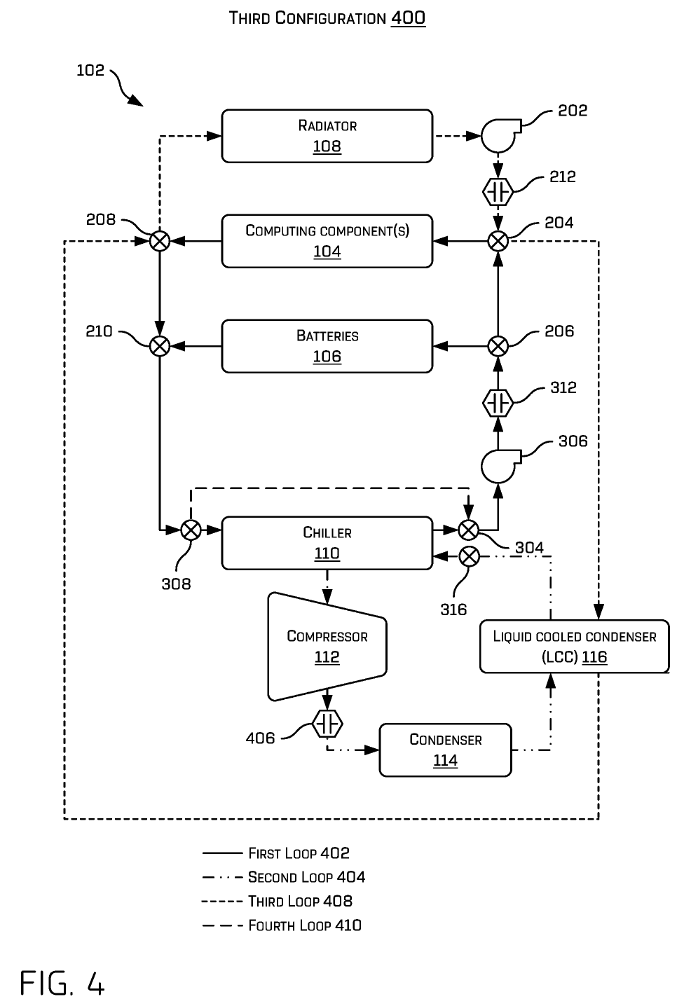

FIG. 4 illustrates a third configuration 400 of the thermal management system 102, according to an embodiment of the present disclosure. As introduced above, in the third configuration 400, the chiller 110 cools the computing components 104 and the batteries 106.

In the third configuration, the second valve 206 directs the coolant flowing from the chiller 110 to the computing components 104 and the batteries 106. The computing components 104 and the batteries 106 may be cooled in parallel. After the coolant flows through the computing components 104, the third valve 208 directs the coolant to the fourth valve 210, whereby the coolant mixes with coolant exiting the batteries 106. From there, the coolant may be routed back to the chiller 110. The progression of the coolant through the chiller 110, the computing components 104, and the batteries 106 may be a first loop 402 of the third configuration 400.

The controller 118 may control (e.g., actuate) settings of the pump 306, the first valve 204, the second valve 206, the third valve 208, the fourth valve 210, the fifth valve 304, and/or the sixth valve 308 to route the coolant according to the third configuration 400. The controller 118 may also control an amount of coolant supplied to the computing components 104 and the batteries 106, respectively, thereby controlling an amount of cooling. Moreover, various sensors (e.g., temperature sensors, pressure sensors, flow rate sensors, etc.) may be disposed about the thermal management system 102 for use by the controller 118.

In an embodiment, the thermal management system 102 may operate according to the third configuration 400 based at least in part on a temperature associated with the thermal management system 102. In an embodiment, the temperature associated with the thermal management system 102 may be a temperature of the coolant exiting the radiator 108. For example, the temperature sensor 212 may measure a temperature of the coolant exiting the radiator 108. In an embodiment, if the temperature measured by the temperature sensor 212 is greater than the second threshold, the controller 118 may configure the thermal management system 102 to the third configuration 400. Noted above, the second temperature threshold may be 55°C. In other words, if the temperature of the coolant is greater than 55°C, the coolant may insufficiently cool the computing components 104.

Although described as measuring the temperature of the coolant exiting the radiator 108, other temperatures may be used and/or temperatures of other components may be used to configure the thermal management system 102 according to the third configuration 400. For example, a temperature of the coolant exiting the chiller 110 may be used to configure the thermal management system 102 to the third configuration 400. As another example, on extreme temperature days, such as when the ambient temperature is greater than a threshold (e.g., above 30°C), the chiller 110 may be used to provide cooling.

In the third configuration 400, coolant flowing through the radiator 108 may be isolated from coolant flowing through the computing components 104 and the batteries 106. However, when the thermal management system 102 converts from the second configuration 300 to the third configuration 400, coolant from the computing components 104 may mix (i.e., combine) with coolant from the batteries 106. This is accomplished via adjusting setting(s) of the second valve 206 when causing coolant to be supplied to the computing components 104.

The refrigerant may have a second loop 404 in the third configuration 400, whereby the refrigerant flows through the chiller 110, the compressor 112, the condenser 114, and the LCC 116. In an embodiment, the LCC 116 may be passive in the third configuration 400 and not provide any cooling to the refrigerant. However, in an embodiment, the LCC 116 may be used to provide cooling to the refrigerant based at least in part on an amount of work performed by the compressor 112, an amount of cooling performed by the condenser 114, a temperature associated with the thermal management system 102 (e.g., temperature of the coolant from the temperature sensor 312), and a pressure of the refrigerant exiting the compressor 112. A pressure sensor 406 may measure a pressure of the refrigerant exiting the compressor 112.

In an embodiment, if the pressure is greater than a threshold pressure (e.g., 2000 kPa), the controller 118 may enlist the LCC 116 to provide supplemental cooling to the refrigerant. Using the LCC 116 may take advantage of cooling offered by the radiator 108. For example, the LCC 116 may fluidly connect to the radiator 108 via the first valve 204 and the third valve 208. The pump 202 may control a flow of coolant through the LCC 116 and back to the radiator 108. Within the LCC 116, however, the refrigerant may transfer heat to coolant flowing through the radiator 108. The first valve 204 permits the flow of coolant from the radiator 108 to the LCC 116, while simultaneously restricting the flow of coolant from the chiller 110 to the radiator 108. Instead, the first valve 204 directs the flow of coolant from the chiller 110 to the computing components 104. In addition, the third valve 208 permits the flow of coolant from the LCC 116 to the radiator 108, while simultaneously directing the flow of coolant exiting the computing components 104 to the chiller 110. The cycle of the coolant to and from the radiator 108 and the LCC 116 may be a third loop 408 of the third configuration 400.

In an embodiment, a portion of the coolant in the first loop 402 may bypass the chiller 110. For example, when the thermal management system 102 transitions from the second configuration 300 to the third configuration 400, the coolant within the computing components 104 is at a higher temperature than the coolant within the batteries 106. When the coolant first combines, given that the coolant exiting the computing components 104 may be warmer than the coolant exiting the batteries 106, the temperature differential may cause a shock to the chiller 110. To avoid this adverse consequence, a portion of the coolant may bypass the chiller 110 via the sixth valve 308. From there, the coolant may be reintroduced downstream of the chiller 110 at the fifth valve 304. This may correspond to a fourth loop 410 of the third configuration 400. In an embodiment, the fourth loop 410 may remain operational until a certain period of time after configuring the thermal management system 102 to the third configuration 400. For example, based on a temperature of the coolant and/or an amount of time after switching to the third configuration 400, the sixth valve 308 may be closed to direct all of the coolant to the chiller 110.

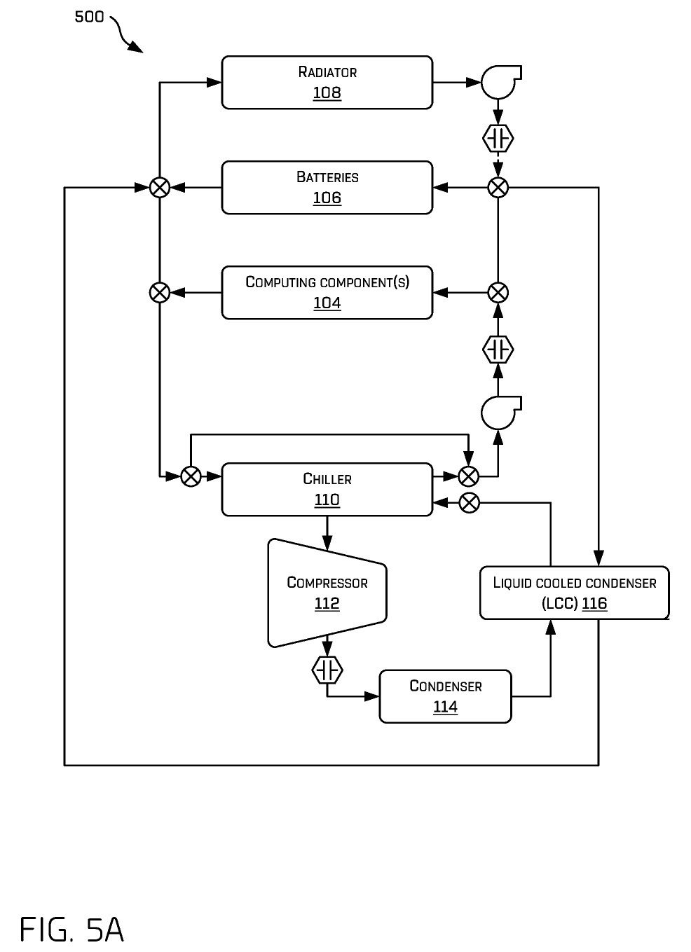

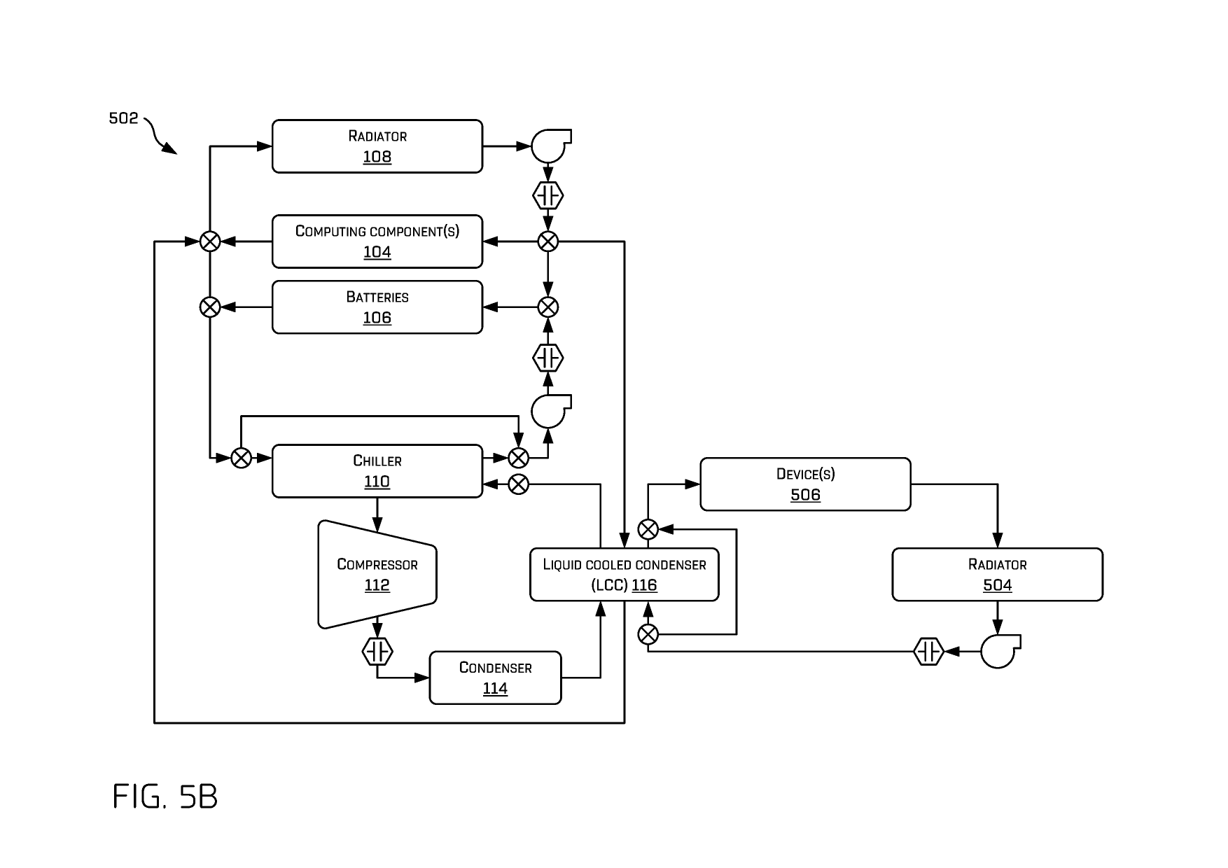

FIGS. 5A and 5B illustrate alternative examples of a thermal management system that provides cooling to the computing components 104 and the batteries 106, according to an embodiment of the present disclosure.

In FIG. 5A, a thermal management system 500 is shown providing cooling to the computing components 104 and the batteries 106. In many regards, the thermal management system 500 may be similar to the thermal management system 102. However, as shown, the computing components 104 and the location of the batteries 106 may be swapped, as compared to the thermal management system 102. In this example, the thermal management system 500 may provide increased cooling to the batteries 106 in the first configuration 200, given that the batteries 106 are located more proximate to the radiator 108. This increase in cooling may be particularly beneficial on warmer days where the batteries 106 are more volatile or susceptible to damage from high temperatures than the computing components.

In FIG. 5B, a thermal management system 502 may include, or fluidly connect to, a radiator 504 and/or device(s) 506. In an embodiment, the radiator 504 cools a coolant to cool the device(s) 506. The device(s) 506 may be representative of any equipment, instrument, hardware, motor, computer, system, appliance, mechanism, unit, etc., that requires cooling. In instances where the radiator 504 is able to provide supplemental cooling, coolant flowing through the radiator 504 may exchange heat with the refrigerant flowing through the LCC 116. Additionally, or alternatively, coolant flowing through the radiator 504 may exchange heat with coolant flowing through the radiator 108. In an embodiment, this supplemental cooling may be provided in the second configuration 300 and/or the third configuration 400 of the thermal management system 102.

In an embodiment, the radiator 504 may provide supplemental cooling based at least in part on a direction of travel of the vehicle 100. For example, the radiator 108 may be located at a first end of the vehicle 100 (e.g., leading end), while the radiator 504 may be located at a second end of the vehicle 100 (e.g., trailing end, etc.). Given the bi-directionality of the vehicle 100, in an embodiment, at least one of the radiator 108 or the radiator 504 may be located at the first end of the vehicle 100 to benefit from an airflow to provide cooling. In an embodiment, the radiator 504 may be used in lieu of the radiator 108 to provide cooling. However, as introduced above, fans may be disposed adjacent to the radiator 108 and/or the radiator 504. Moreover, in an embodiment, the radiator 108 and the radiator 504 may be located at the same end of the vehicle 100.

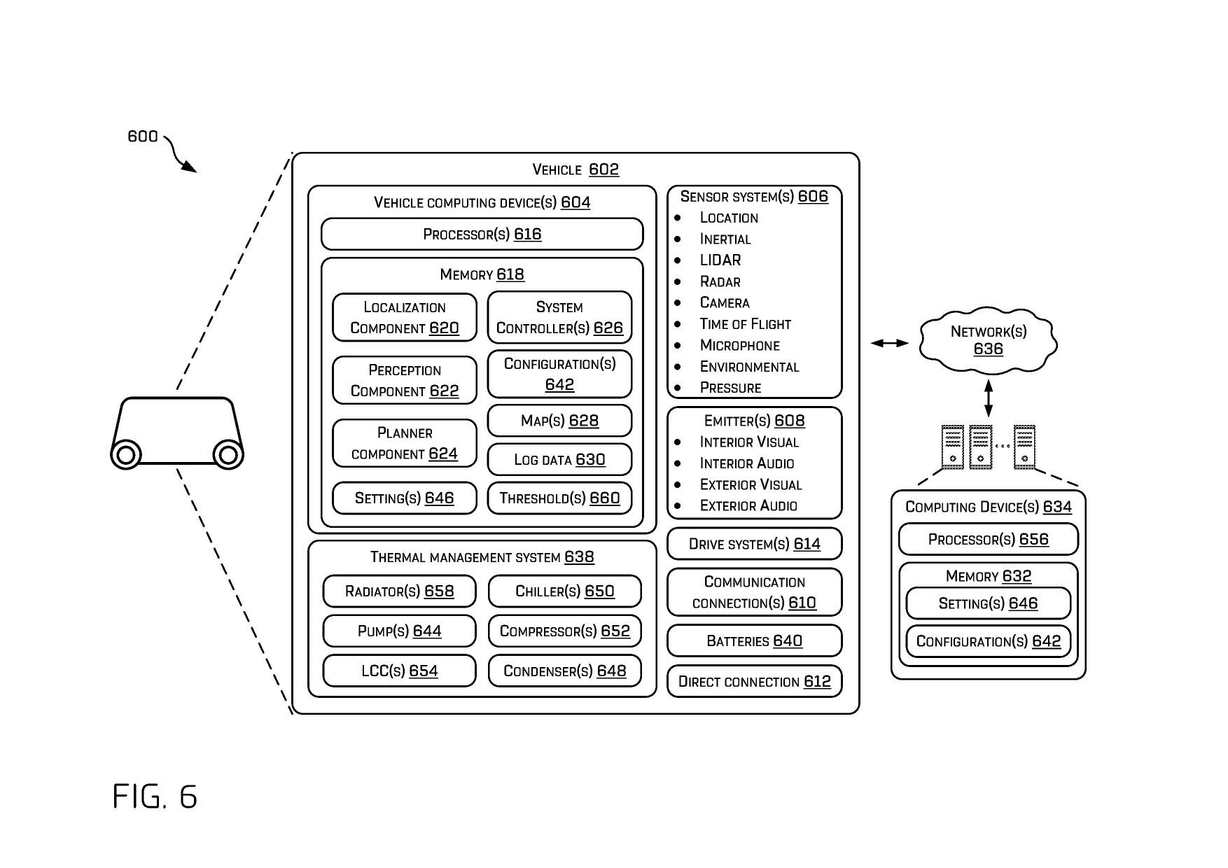

FIG. 6 is a block diagram of an example system 600 for implementing the techniques described herein, according to an embodiment of the present disclosure. In at least one example, the system 600 may include a vehicle, such as a vehicle 602. The vehicle 602 may be the same as, or different than, the vehicle 100. The vehicle 602 may include one or more vehicle computing device(s) 604, one or more sensor system(s) 606, one or more emitter(s) 608, one or more communication connection(s) 610, at least one direct connection 612, and drive system(s) 614.

The vehicle computing device(s) 604 may include one or more processor(s) 616 and memory 618 communicatively coupled with the one or more processor(s) 616. In the illustrated example, the vehicle 602 is an autonomous vehicle; however, the vehicle 602 could be any other type of vehicle, such as a semi-autonomous vehicle, or any other system having at least an image capture device (e.g., a camera enabled smartphone). In the illustrated example, the memory 618 of the vehicle computing device(s) 604 stores a localization component 620, a perception component 622, a planner component 624, one or more system controller(s) 626, map(s) 628, and log data 630. Though depicted in FIG. 6 as residing in the memory 618 for illustrative purposes, it is contemplated that the localization component 620, the perception component 622, the planner component 624, the system controller(s) 626, and the map(s) 628 may additionally, or alternatively, be accessible to the vehicle 602 (e.g., stored on, or otherwise accessible by, memory remote from the vehicle 602, such as, for example, on memory 632 of computing device(s) 634).

In at least one example, the localization component 620 may include functionality to receive data from the sensor system(s) 606 to determine a position and/or orientation of the vehicle 602 (e.g., one or more of an x-, y-, z-position, roll, pitch, or yaw). For example, the localization component 620 may include and/or request / receive a map of an environment and may continuously determine a location and/or orientation of the autonomous vehicle within the map. In some instances, the localization component 620 may utilize SLAM (simultaneous localization and mapping), CLAMS (calibration, localization and mapping, simultaneously), relative SLAM, bundle adjustment, non-linear least squares optimization, or the like to receive image data, LIDAR data, radar data, IMU data, GPS data, wheel encoder data, and the like to accurately determine a location of the autonomous vehicle. In some instances, the localization component 620 may provide data to various components of the vehicle 602 to determine an initial position of an autonomous vehicle for generating a path polygon associated with the vehicle path, as discussed herein.

In an embodiment, the perception component 622 may include functionality to perform object detection, segmentation, and/or classification. In some examples, the perception component 622 may provide processed sensor data that indicates a presence of an object (e.g., entity) that is proximate to the vehicle 602 and/or a classification of the object as an object type (e.g., car, pedestrian, cyclist, animal, building, tree, road surface, curb, sidewalk, unknown, etc.). In some examples, the perception component 622 may provide processed sensor data that indicates a presence of a stationary entity that is proximate to the vehicle 602 and/or a classification of the stationary entity as a type (e.g., building, tree, road surface, curb, sidewalk, unknown, etc.).

In additional or alternative examples, the perception component 622 may provide processed sensor data that indicates one or more characteristics associated with a detected object (e.g., a tracked object) and/or the environment in which the object is positioned. In some examples, characteristics associated with an object may include, but are not limited to, an x-position (global and/or local position), a y-position (global and/or local position), a z-position (global and/or local position), an orientation (e.g., a roll, pitch, yaw), an object type (e.g., a classification), a velocity of the object, an acceleration of the object, an extent of the object (size), etc. Characteristics associated with the environment may include, but are not limited to, a presence of another object in the environment, a state of another object in the environment, a time of day, a day of a week, a season, a weather condition, an indication of darkness/light, etc.

In general, the planner component 624 may determine a path for the vehicle 602 to follow to traverse through an environment. For example, the planner component 624 may determine various routes and trajectories and various levels of detail. For example, the planner component 624 may determine a route to travel from a first location (e.g., a current location) to a second location (e.g., a target location). For the purpose of this discussion, a route may include a sequence of waypoints for travelling between two locations. As non-limiting examples, waypoints include streets, intersections, global positioning system (GPS) coordinates, etc. Further, the planner component 624 may generate an instruction for guiding the vehicle 602 along at least a portion of the route from the first location to the second location. In at least one example, the planner component 624 may determine how to guide the vehicle 602 from a first waypoint in the sequence of waypoints to a second waypoint in the sequence of waypoints. In some examples, the instruction may be a trajectory, or a portion of a trajectory. In some examples, multiple trajectories may be substantially simultaneously generated (e.g., within technical tolerances) in accordance with a receding horizon technique, wherein one of the multiple trajectories is selected for the vehicle 602 to navigate.

The system controller(s) 626 may be configured to control steering, propulsion, braking, safety, emitters, communication, and other systems of the vehicle 602. The system controller(s) 626 may communicate with and/or control corresponding systems of the drive system(s) 614 and/or other components of the vehicle 602.

The memory 618 may further include the map(s) 628 that may be used by the vehicle 602 to navigate within the environment. For the purpose of this discussion, a map may be any number of data structures modeled in two dimensions, three dimensions, or N-dimensions that are capable of providing information about an environment, such as, but not limited to, topologies (such as intersections), streets, mountain ranges, roads, terrain, and the environment in general. In some instances, a map may include, but is not limited to: texture information (e.g., color information (e.g., RGB color information, Lab color information, HSV/HSL color information), and the like), intensity information (e.g., lidar information, radar information, and the like); spatial information (e.g., image data projected onto a mesh, individual “surfels” (e.g., polygons associated with individual color and/or intensity)), reflectivity information (e.g., specularity information, retroreflectivity information, BRDF information, BSSRDF information, and the like). In one example, a map may include a three-dimensional mesh of the environment. In some examples, the vehicle 602 may be controlled based at least in part on the map(s) 628. That is, the map(s) 628 may be used in connection with the localization component 620, the perception component 622, and/or the planner component 624 to determine a location of the vehicle 602, detect objects in an environment, and/or generate routes and/or trajectories to navigate within an environment. Additionally, in some examples, the map(s) 628 may be used in connection with a tracker component to determine a position and/or orientation of the vehicle with respect to a planned trajectory, such as based on steering angles, velocities, accelerations, drive direction, drive gear, and/or gravity acceleration.

In some examples, the map(s) 628 may be stored on a computing device(s) (such as the computing device(s) 634) accessible via network(s) 636. In some examples, one or more of the map(s) 628 may be stored based on, for example, a characteristic (e.g., type of entity, time of day, day of week, season of the year, etc.). Storing one or more of the map(s) 628 may have similar memory requirements, but increase the speed at which data in a map may be accessed.

The log data 630 may represent data input and/or output by each of the localization component 620, the perception component 622, the planner component 624, the system controller(s) 626, and/or outputs of various subcomponents thereof. In at least one example, the log data 630mayinclude sensor data captured and provided to one or more of the components of the vehicle computing device(s) 604 by the sensor system(s) 606.

As can be understood, the components discussed herein (e.g., the localization component 620, the perception component 622, the planner component 624, the system controller(s) 626, and the map(s) 628 are described as divided for illustrative purposes. However, the operations performed by the various components may be combined or performed in any other component. For example, in the illustrative example, the functions of a tracker component as described above may be performed by the planner component 624. However, in other examples, the tracker component may include a separate component independent of the planner component 624.

In an embodiment, aspects of some or all of the components discussed herein may include any models, techniques, and/or machine learning techniques. For example, in some instances, the components in the memory 618 (and the memory 632, discussed below) may be implemented as a neural network.

The sensor system(s) 606 may include lidar sensors, radar sensors, ultrasonic transducers, sonar sensors, location sensors (e.g., GPS, compass, etc.), inertial sensors (e.g., inertial measurement units (IMUs), accelerometers, magnetometers, gyroscopes, etc.), cameras (e.g., RGB, IR, intensity, depth, time of flight, etc.), microphones, wheel encoders, environment sensors (e.g., temperature sensors, humidity sensors, light sensors, pressure sensors, etc.), etc. The sensor system(s) 606 may include multiple instances of each of these or other types of sensors. For instance, the lidar sensors may include individual lidar sensors located at the corners, front, back, sides, and/or top of the vehicle 602. As another example, the camera sensors may include multiple cameras disposed at various locations about the exterior and/or interior of the vehicle 602. The sensor system(s) 606 may provide input to the vehicle computing device(s) 604. Additionally, or alternatively, the sensor system(s) 606 may send sensor data, via the one or more network(s) 636, to the one or more computing device(s) 634 at a particular frequency, after a lapse of a predetermined period of time, in near real-time, etc.

The vehicle 602 may also include one or more emitter(s) 608 for emitting light and/or sound, as described above. The emitter(s) 608 in this example include interior audio and visual emitters to communicate with passengers of the vehicle 602. By way of example and not limitation, interior emitters may include speakers, lights, signs, display screens, touch screens, haptic emitters (e.g., vibration and/or force feedback), mechanical actuators (e.g., seatbelt tensioners, seat positioners, headrest positioners, etc.), and the like. The emitter(s) 608 in this example also include exterior emitters. By way of example and not limitation, the exterior emitters in this example include lights to signal a direction of travel or other indicator of vehicle action (e.g., indicator lights, signs, light arrays, etc.), and one or more audio emitters (e.g., speakers, speaker arrays, horns, etc.) to audibly communicate with pedestrians or other nearby vehicles, one or more of which comprising acoustic beam steering technology.

The vehicle 602 may also include the communication connection(s) 610 that enable communication between the vehicle 602 and one or more other local or remote computing device(s). For instance, the communication connection(s) 610 may facilitate communication with other local computing device(s) on the vehicle 602 and/or the drive system(s) 614. Also, the communication connection(s) 610 may allow the vehicle to communicate with other nearby computing device(s) (e.g., the computing device(s) 634, other nearby vehicles, etc.) and/or one or more remote sensor system(s) for receiving sensor data.

The communication connection(s) 610 may include physical and/or logical interfaces for connecting the vehicle computing device(s) 604 to another computing device or a network, such as the network(s) 636. For example, the communication connection(s) 610 may enable Wi-Fi-based communication such as via frequencies defined by the IEEE 802.11 standards, short range wireless frequencies such as Bluetooth, cellular communication (e.g., 2G, 3G, 4G, 4G LTE, 5G, etc.) or any suitable wired or wireless communications protocol that enables the respective computing device to interface with the other computing device(s).

In at least one example, the vehicle 602 may include the drive system(s) 614. In some examples, the vehicle 602 may have one of the drive system(s) 614. In at least one example, if the vehicle 602 has more than one of the drive system(s) 614, individual ones of the drive system(s) 614 may be positioned on opposite ends of the vehicle 602 (e.g., the front and the rear, etc.). In at least one example, the drive system(s) 614 may include one or more sensor systems to detect conditions of the drive system(s) 614 and/or the surroundings of the vehicle 602. By way of example and not limitation, the sensor system(s) may include one or more wheel encoders (e.g., rotary encoders) to sense rotation of the wheels of the drive system(s) 614, inertial sensors (e.g., inertial measurement units, accelerometers, gyroscopes, magnetometers, etc.) to measure orientation and acceleration associated with the drive system(s) 614, cameras or other image sensors, ultrasonic sensors to acoustically detect objects in the surroundings of the drive system(s) 614, lidar sensors, radar sensors, etc. Some sensors, such as the wheel encoders may be unique to the drive system(s) 614. In some cases, the sensor system(s) on the drive system(s) 614 may overlap or supplement corresponding systems of the vehicle 602 (e.g., the sensor system(s) 606).

The drive system(s) 614 may include many of the vehicle systems, including batteries 640, a motor to propel the vehicle, an inverter to convert direct current from the batteries 640 into alternating current for use by other vehicle systems, a steering system including a steering motor and steering rack (which can be electric), a braking system including hydraulic or electric actuators, a suspension system including hydraulic and/or pneumatic components, a stability control system for distributing brake forces to mitigate loss of traction and maintain control, an HVAC system, lighting (e.g., lighting such as head/tail lights to illuminate an exterior surrounding of the vehicle), and one or more other systems (e.g., cooling system, safety systems, onboard charging system, other electrical components such as a DC/DC converter, a high voltage junction, a high voltage cable, charging system, charge port, etc.). Additionally, the drive system(s) 614 may include a drive system controller which may receive and preprocess data from the sensor system(s) and to control operation of the various vehicle systems. In some examples, the drive system controller may include one or more processors and memory communicatively coupled with the one or more processors. The memory may store one or more modules to perform various functionalities of the drive system(s) 614. Furthermore, the drive system(s) 614 may also include one or more communication connection(s) that enable communication by the respective drive system with one or more other local or remote computing device(s).

In at least one example, the at least one direct connection 612 may provide a physical interface to couple the drive system(s) 614 with the body of the vehicle 602. For example, the at least one direct connection 612 may allow the transfer of energy, fluids, air, data, etc. between the drive system(s) 614 and the vehicle 602. In some instances, the at least one direct connection 612 may further releasably secure the drive system(s) 614 to the body of the vehicle 602.

In at least one example, the localization component 620, the perception component 622, the planner component 624, and/or the one or more system controller(s) 626, and/or various components thereof, may process sensor data, as described above, and may send their respective outputs as the log data 630, over the one or more network(s) 636, to the computing device(s) 634. In at least one example, the vehicle computing device(s) 604 may send the log data 630 to the computing device(s) 634 at a particular frequency, after a lapse of a predetermined period of time, in near real-time, etc.

In some examples, the vehicle 602 may send sensor data to the computing device(s) 634 via the network(s) 636. In some examples, the vehicle 602 may receive sensor data from the computing device(s) 634 via the network(s) 636. The sensor data may include raw sensor data and/or processed sensor data and/or representations of sensor data. In some examples, the sensor data (raw or processed) may be sent and/or received as one or more log files.

The vehicle 602 may include a thermal management system 638 that provides cooling to various components of the vehicle 602. For example, the thermal management system 638 may provide cooling to the vehicle computing device(s) 604, including but not limited to, the localization component 620, the perception component 622, the planner component 624, the system controller(s) 626. In addition, the thermal management system 638 may provide cooling to the batteries 640. Still, in an embodiment, the thermal management system 638 may provide cooling to the sensor system(s) 606, the emitter(s) 608, the drive system(s) 614, the communication connection(s) 610, and/or any other components of the vehicle 602 that require cooling.

In an embodiment, the thermal management system 638 may provide cooling to the vehicle computing device(s) 604 and/or the batteries 640 based at least in part on sensor data generated by the sensor system(s) 606. For example, the sensor system(s) 606 may monitor a temperature of the vehicle computing device(s) 604 and/or the batteries 640. In an embodiment, the thermal management system 638 may operate according to certain configuration(s) 642 based at least in part on the temperature of the vehicle computing device(s) 604 and/or the batteries 640. For example, the thermal management system 638 may include, or operate according to, at least a first configuration, a second configuration, and a third configuration.

Whether the thermal management system 638 operates at the first configuration, the second configuration, or the third configuration, may be based on comparing the temperature of the vehicle computing device(s) 604 and/or the batteries 640 to one or more threshold(s) 660. The threshold(s) 660 may be associated with preferred, desired, or maximum operating temperatures of the vehicle computing device(s) 604 and/or the batteries 640. For example, if the temperature is less than a first threshold (e.g., 35°C), the thermal management system 638 may operate at the first configuration. If the temperature is greater than the first temperature threshold, but less a second temperature threshold (e.g., 55°C), the thermal management system 638 may operate at the second configuration. If the temperature is greater than the second temperature threshold, the thermal management system 638 may operate at the third configuration. However, the temperature for controlling the thermal management system 638 may also be associated with an environment or other temperatures associated with the thermal management system 638. In an embodiment, the vehicle computing device(s) 604 may be configured to receive sensor data associated with the temperature, and compare the temperature to the threshold(s) 660 for determining the configuration(s) 642 by which to operate the thermal management system 638. In this sense, the vehicle computing device(s) 604 may be responsible for carrying out some, or all, of the operations associated with the thermal management system 638.

In the first configuration, radiator(s) 658 of the thermal management system 638 provide cooling to the vehicle computing device(s) 604 and/or the batteries 640. For example, coolant may flow from the radiator(s) 658 to the vehicle computing device(s) 604 and/or the batteries 640. In an embodiment, the vehicle computing device(s) 604 and/or the batteries 640 may be cooled in parallel. Moreover, various pump(s) 644, junction(s), valve(s), etc., may be controlled for routing the coolant to and from the radiator(s) 658. The radiator(s) 658 may be located at either the first end or the second end of the vehicle 602, and/or fan(s) may provide airflow over/through the radiator(s) 658. Moreover, the vehicle 602 may include more than one of the radiator(s) 658.

In an embodiment, the thermal management system 638 may operate according to certain setting(s) 646. For example, the setting(s) 646 may be associated with a speed of the pump(s) 644, positions of valve(s), etc., to provide cooling to the vehicle computing device(s) 604 and/or the batteries 640. Moreover, the vehicle computing device(s) 604 may continuously receive the sensor data from the sensor system(s) 606 for making adjustments to the thermal management system 638, such as the setting(s) 646, to provide proper cooling to the vehicle computing device(s) 604 and/or the batteries 640.

In the second configuration, the radiator(s) 658 may provide cooling to the vehicle computing device(s) 604 and chiller(s) 650 of the thermal management system 638 may provide cooling to the batteries 640. For example, a refrigerant that flows through condenser(s) 648, chiller(s) 650, and compressor(s) 652 may cool a coolant flowing through the batteries 640. Within the chiller(s) 650, the refrigerant may exchange heat with the coolant in order to provide cooling to the batteries 640.

In the second configuration, the setting(s) 646 may be used to control the pump(s) 644, the valve(s), etc. For example, valve(s) that previously fluidly connected the radiator(s) 658 to the batteries 640 (e.g., in the first configuration) may be used to isolate the radiator(s) 658 from the batteries 640. Moreover, the setting(s) 646 may be used to control one or more of the pump(s) 644 to supply the coolant to the batteries 640. In an embodiment, the vehicle computing device(s) 604 may be cooled via first coolant flowing through the radiator(s) 658, while the batteries 640 may be cooled via second coolant flowing through the chiller(s) 650.

In the third configuration, the chiller(s) 650 provide cooling to the vehicle computing device(s) 604 and the batteries 640. For example, the refrigerant flowing through the condenser(s) 648 may cool a coolant that flows through the vehicle computing device(s) 604 and the batteries 640. In the third configuration, the setting(s) 646 may be used to control the pump(s) 644, the valve(s), etc. For example, valve(s) that previously fluidly connected the radiator(s) 658 to the vehicle computing device(s) 604 (e.g., in the first configuration or the second configuration) may be used to isolate the radiator(s) 658 from the vehicle computing device(s) 604. Moreover, the setting(s) 646 may be used to control one or more of the pump(s) 644 to supply the coolant to the vehicle computing device(s) 604 and the batteries 640. In an embodiment, the vehicle computing device(s) 604 and/or the batteries 640 may be cooled in parallel.

The thermal management system 638 is further shown including liquid cooled condensers (LCCs) 654. In an embodiment, the LCC(s) 654 may be used to provide supplemental cooling to the refrigerant in the third configuration of the thermal management system 638. In an embodiment, the LCC(s) 654 is utilized based on an amount of work required of the compressor(s) 652, a pressure of the refrigerant exiting the compressor(s) 652, a temperature associated with the thermal management system 638 (e.g., a temperature of coolant exiting the chiller(s) 650, ambient temperature, etc.), etc. Here, the vehicle computing device(s) 604 may be configured to compare the amount of work, pressure, temperature, etc., to the threshold(s) 660. If the amount of work, pressure, temperature, etc., is greater than the threshold(s) 660, the vehicle computing device(s) 604 may configure the LCC(s) 654 to provide cooling to the refrigerant.

In an embodiment, configuring the LCC(s) 654 may include fluidly connecting the LCC(s) 654 to the radiator(s) 658. Coolant may be routed from the radiator(s) 658 to the LCC(s) 654, whereby the coolant may exchange heat with the refrigerant flowing through the LCC(s) 654. The vehicle computing device(s) 604 may control the setting(s) 646 of the pump(s) 644, valve(s), etc., for fluidly connecting the radiator(s) 658 to the LCC(s) 654.

As introduced above, the vehicle computing device(s) 604 may continuously receive the sensor data for comparing the sensor data to the threshold(s) 660 for determining the configuration(s) 642 of the thermal management system 638. The thermal management system 638 may therefore dynamically switch between the configuration(s) 642. Moreover, the vehicle computing device(s) 604 may operate according to the setting(s) 646 for the configuration(s) 642, respectively.

As introduced above, the vehicle 602 may be communicatively coupled to the computing device(s) 634. In an embodiment, the computing device(s) 634 may have access to, or store, the setting(s) 646 and/or the configuration(s) 642. For example, the vehicle 602 may transmit the sensor data to the computing device(s) 634, and the computing device(s) 634 may determine the setting(s) 646 and/or the configuration(s) 642. Therein, the computing device(s) 634 may communicate to the vehicle 602 to cause the vehicle 602, or the thermal management system 638, to operate according to the setting(s) 646 and/or the configuration(s) 642. In an embodiment, the computing device(s) 634 may include one or more input/output (I/O) devices, such as via one or more interfaces, that display the setting(s) 646 and/or the configuration(s) 642 of the vehicle 602.

The processor(s) 616 and 656 be any suitable processor capable of executing instructions to process data and perform operations as described herein. By way of example and not limitation, the processor(s) 616 and 656 may comprise one or more Central Processing Units (CPUs), Graphics Processing Units (GPUs), or any other device or portion of a device that processes electronic data to transform that electronic data into other electronic data that may be stored in registers and/or memory. In some examples, integrated circuits (e.g., ASICs, etc.), gate arrays (e.g., FPGAs, etc.), and other hardware devices may also be considered processors in so far as they are configured to implement encoded instructions.

The memory 618 and 632 are examples of non-transitory computer-readable media. The memory 618 and 632 may store an operating system and one or more software applications, instructions, programs, and/or data to implement the methods described herein and the functions attributed to the various systems. In various implementations, the memory may be implemented using any suitable memory technology, such as static random access memory (SRAM), synchronous dynamic RAM (SDRAM), nonvolatile/Flash-type memory, or any other type of memory capable of storing information. The architectures, systems, and individual elements described herein may include many other logical, programmatic, and physical components, of which those shown in the accompanying figures are merely examples that are related to the discussion herein.

In some instances, aspects of some or all of the components discussed herein can include any models, algorithms, and/or machine learning algorithms. For example, in some instances, the components in the memory 618 and 632 can be implemented as a neural network.

As described herein, an exemplary neural network is an algorithm that passes input data through a series of connected layers to produce an output. Each layer in a neural network may also comprise another neural network, or may comprise any number of layers (whether convolutional or not). As may be understood in the context of this disclosure, a neural network may utilize machine learning, which may refer to a broad class of such algorithms in which an output is generated based on learned parameters.

Although discussed in the context of neural networks, any type of machine learning may be used consistent with this disclosure. For example, machine learning or machine-learned algorithms may include, but are not limited to, regression algorithms (e.g., ordinary least squares regression (OLSR), linear regression, logistic regression, stepwise regression, multivariate adaptive regression splines (MARS), locally estimated scatterplot smoothing (LOESS)), instance-based algorithms (e.g., ridge regression, least absolute shrinkage and selection operator (LASSO), elastic net, least-angle regression (LARS)), decisions tree algorithms (e.g., classification and regression tree (CART), iterative dichotomiser 3 (ID3), Chi-squared automatic interaction detection (CHAID), decision stump, conditional decision trees), Bayesian algorithms (e.g., naïve Bayes, Gaussian naïve Bayes, multinomial naïve Bayes, average one-dependence estimators (AODE), Bayesian belief network (BNN), Bayesian networks), clustering algorithms (e.g., k-means, k-medians, expectation maximization (EM), hierarchical clustering), association rule learning algorithms (e.g., perceptron, back-propagation, hopfield network, Radial Basis Function Network (RBFN)), deep learning algorithms (e.g., Deep Boltzmann Machine (DBM), Deep Belief Networks (DBN), Convolutional Neural Network (CNN), Stacked Auto-Encoders), Dimensionality Reduction Algorithms (e.g., Principal Component Analysis (PCA), Principal Component Regression (PCR), Partial Least Squares Regression (PLSR), Sammon Mapping, Multidimensional Scaling (MDS), Projection Pursuit, Linear Discriminant Analysis (LDA), Mixture Discriminant Analysis (MDA), Quadratic Discriminant Analysis (QDA), Flexible Discriminant Analysis (FDA)), Ensemble Algorithms (e.g., Boosting, Bootstrapped Aggregation (Bagging), AdaBoost, Stacked Generalization (blending), Gradient Boosting Machines (GBM), Gradient Boosted Regression Trees (GBRT), Random Forest), SVM (support vector machine), supervised learning, unsupervised learning, semi-supervised learning, etc.

Additional examples of architectures include neural networks such as ResNet50, ResNet52, ResNet101, VGG, DenseNet, PointNet, and the like.

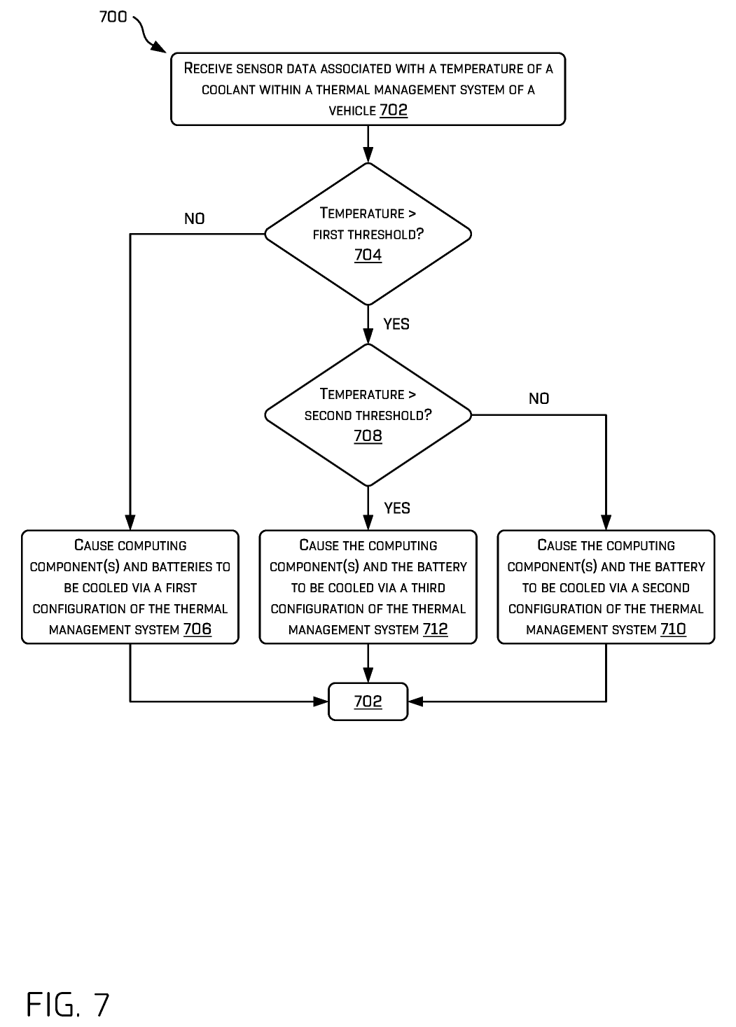

FIGS. 7-9 illustrate example processes in accordance with examples of the disclosure. These processes are illustrated as a logical flow graph, each operation of which represents a sequence of operations that may be implemented in hardware, software, or a combination thereof. In the context of software, the operations represent computer-executable instructions stored on one or more computer-readable storage media that, when executed by one or more processors, perform the recited operations. Generally, computer-executable instructions include routines, programs, objects, components, data structures, and the like that perform particular functions or implement particular abstract data types. The order in which the operations are described is not intended to be construed as a limitation, and any number of the described operations may be omitted or combined in any order and/or in parallel to implement the processes. For example, some or all of the processes may be performed by one or more components in FIGS. 1-6, as described herein.

FIG. 7 illustrates an example process 700 associated with providing cooling to computing components and/or batteries of a vehicle, according to an embodiment of the present disclosure. In an embodiment, the process 700 may be implemented at least in part by the vehicle computing device(s) 604.

At 702, the process 700 may include receiving sensor data associated with a temperature of a coolant within a thermal management system of a vehicle. For example, sensor data may be generated from one or more sensor(s) of the vehicle, where the sensor data indicates a temperature of a coolant flowing through the thermal management system. In an embodiment, the temperature may be a temperature of coolant exiting a radiator of the thermal management system. However, the temperature may also be associated with an environment of the vehicle, temperatures of the computing components, the batteries, etc.

At 704, the process 700 may include determining whether the temperature is greater than a first threshold. For example, the temperature (from 702) may be compared to a first temperature threshold. In an embodiment, the first temperature threshold may be 35°C, which is associated with a maximum operating temperature of the batteries. If at 704 the process 700 determines that the temperature is not greater than the first threshold, the process 700 may follow the “NO” route and proceed to 706.

At 706, the process 700 may include causing computing component(s) and batteries to be cooled via a first configuration of the thermal management system. In an embodiment, the first configuration of the thermal management system may include cooling the computing component(s) and the batteries via coolant flowing through a radiator of the thermal management system. The radiator may be fluidly connected to the computing component(s) and the batteries via various valve(s), pump(s), junction(s), fittings, etc. Moreover, the valve(s), pump(s), junction(s), fittings, etc., may be controlled to cool the computing component(s) and the batteries according to their desired settings. From 706, the process 700 may proceed to 702.

Returning to 704, if the process 700 determines that the temperature is greater than the first threshold, the process 700 may follow the “YES” route and proceed to 708. At 708, the process 700 may include determining whether the temperature is greater than a second threshold. For example, the temperature (from 702) may be compared to a second temperature threshold. In an embodiment, the second temperature threshold may be 55°C, which is associated with a maximum operating temperature of the computing component(s). If at 708 the process 700 determines that the temperature is not greater than the second threshold, the process 700 may follow the “NO” route and proceed to 710.

At 710, the process 700 may include causing computing component(s) and batteries to be cooled via a second configuration of the thermal management system. In an embodiment, the second configuration of the thermal management system may include cooling the computing component(s) via coolant flowing through the radiator of the thermal management system, and cooling the batteries via coolant flowing through a chiller of the thermal management system. A condenser, as discussed herein, may be fluidly connected to the chiller, a compressor, and/or a LCC. In the second configuration, the radiator may be fluidly disconnected, or isolated, from the batteries. In other words, the computing components may be fluidly isolated from the batteries. Coolant that provides cooling to the batteries may be conditioned within the chiller, whereby the refrigerant flows through the chiller, the compressor, and the condenser. The valve(s), pump(s), junction(s), fittings, etc., may be controlled to fluidly isolate the computing components from the batteries, to control the flow of coolant through the batteries, and/or to control the flow of coolant through the chiller. The compressor, the condenser, the LCC may also be controlled. From 710, the process 700 may proceed to 702.

Returning to 708, if process 700 determines that the temperature is greater than the second threshold, the process 700 may follow the “YES” route and proceed to 712. At 712, the process 700 may include cooling computing component(s) and batteries via a third configuration of the thermal management system. In an embodiment, the third configuration of the thermal management system may include cooling the computing component(s) and the batteries via a coolant flowing through the chiller of the thermal management system. In the third configuration, the computing component(s) may be fluidly disconnected from the radiator. Instead, the computing component(s) may be fluidly connected to the chiller and the computing components may be cooled via coolant flowing through the chiller. The valve(s), pump(s), junction(s), fittings, etc., may be controlled to fluidly isolate the computing component(s) from the radiator, and fluidly connect the computing component(s) to the chiller. From 712, the process 700 may proceed to 702.

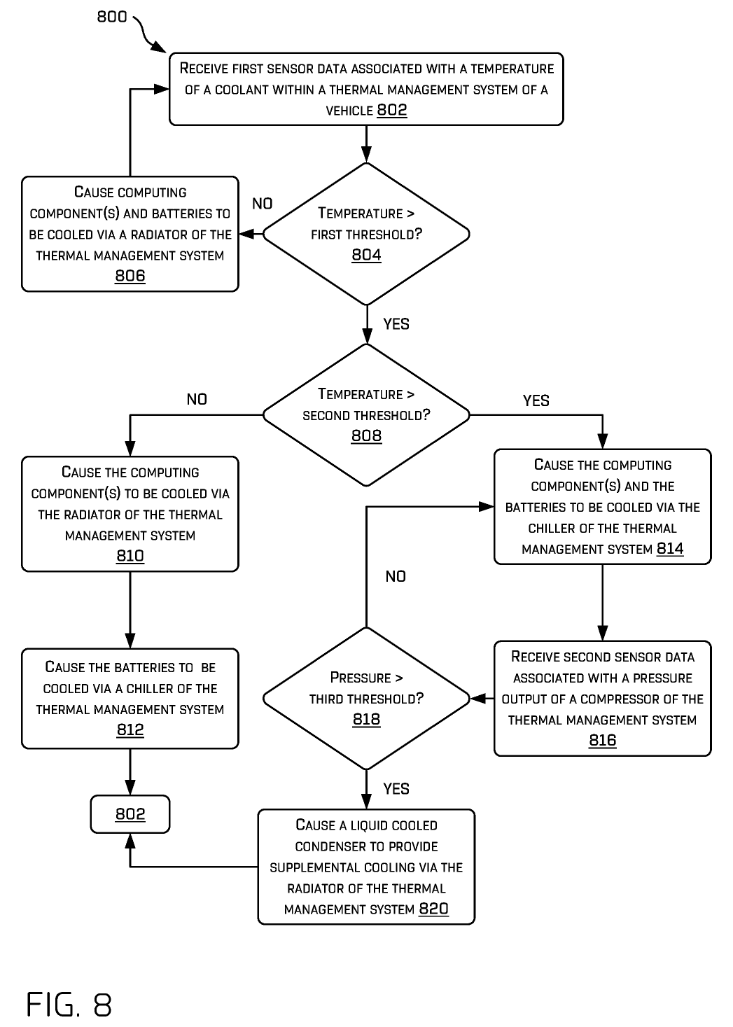

FIG. 8 illustrates an example process 800 associated with cooling computing components and/or batteries of a vehicle, according to an embodiment of the present disclosure. In an embodiment, the process 800 may be implemented at least in part by the vehicle computing device(s) 604.

At 802, the process 800 may include receiving sensor data associated with a temperature of a coolant within a thermal management system of a vehicle. For example, sensor data may be generated from one or more sensor(s) of the vehicle, where the sensor data indicates a temperature of a coolant flowing through the thermal management system. In an embodiment, the temperature may be a temperature of coolant exiting a radiator of the thermal management system. However, the temperature may also be associated with an environment of the vehicle, temperatures of the computing components, the batteries, etc.

At 804, the process 800 may include determining whether the temperature is greater than a first threshold. For example, the temperature (from 802) may be compared to a first temperature threshold. In an embodiment, the first temperature threshold may be 35°C, which is associated with a maximum operating temperature of the batteries. If at 804, the process 800 determines that the temperature is not greater than the first threshold, the process 800 may follow the “NO” route and proceed to 806.

At 806, the process 800 may include causing computing component(s) and batteries to be cooled via a radiator of the thermal management system. The radiator may be fluidly connected to the computing component(s) and the batteries via various valve(s), pump(s), junction(s), fittings, etc. Moreover, the valve(s), pump(s), junction(s), fittings, etc., may be controlled to cool the computing component(s) and the batteries according to their desired settings. From 806, the process 800 may proceed to 802.

Returning to 804, if the process 800 determines that the temperature is greater than the first threshold, the process 800 may follow the “YES” route and proceed to 808. At 808, the process 800 may include determining whether the temperature is greater than a second threshold. For example, the temperature (from 802) may be compared to a second temperature threshold. In an embodiment, the second temperature threshold may be 55°C, which is associated with a maximum operating temperature of the computing component(s). If at 808 the process 800 determines that the temperature is not greater than the second threshold, the process 800 may follow the “NO” route and proceed to 810.

At 810, the process 800 may include causing the computing component(s) to be cooled via the radiator of the thermal management system. For example, coolant flowing through the radiator may cool the computing component(s). The valve(s), pump(s), junction(s), fittings, etc., of the thermal management system may be controlled to cool the computing component(s). Moreover, since the radiator cools the computing component(s), the radiator and the computing component(s) may be fluidly isolated from the batteries.

At 812, the process 800 may include causing the batteries to be cooled via a chiller of the thermal management system. For example, a chiller of the thermal management system may exchange heat with coolant flowing through the batteries. The coolant flowing through the chiller and the batteries may be fluidly isolated from the coolant flowing through the computing component(s). The valve(s), pump(s), junction(s), fittings, etc., of the thermal management system may be controlled to cool the batteries. From 812, the process may proceed to 802.

Returning to 808, if the process 800 determines that the temperature is greater than the second threshold, the process 800 may follow the “YES” route and proceed to 814. At 814, the process 800 may include causing the computing component(s) and the batteries to be cooled via the chiller of the thermal management system. Cooling the computing component(s) and the batteries via the chiller may include fluidly isolating the radiator from the computing component(s), as well as other components of the thermal management system. In an embodiment, the valve(s), pump(s), junction(s), fittings, etc., of the thermal management system may be controlled to cool the computing component(s) and the batteries via the coolant flowing through the chiller. For example, valves that previously fluidly isolated the computing component(s) from the batteries may be used to fluidly connect the computing component(s) from the batteries.

At 816, the process 800 may include receiving second sensor data associated with a pressure output of a compressor of the thermal management system. For example, sensor data may be received, whereby the sensor data may be associated with a pressure of the refrigerant exiting the compressor. In an embodiment, the pressure may be associated with an amount of work required by the compressor to cool the coolant in order to provide cooling to the computing component(s) and the batteries (i.e., at 814).

At 818, the process 800 may include determining whether the pressure is greater than a third threshold. For example, the third threshold may be associated with a pressure threshold (e.g., 2000 kPa), whereby a LCC may provide supplemental cooling to the refrigerant via a radiator. If at 818, the process 800 determines that the pressure is not greater than the pressure threshold, the process 800 may follow the “NO” route and proceed to 814. In other words, if the thermal management system does not need supplemental cooling via the LCC and the radiator, the computing component(s) and the batteries may be cooled via the chiller. In an embodiment, rather than measuring a pressure of the refrigerant exiting the compressor, the process 800 may determine a temperature of the coolant, the refrigerant, the computing component(s), the batteries, etc., for determining whether to utilize the LCC and the radiator for supplemental cooling.

Returning to 818, if the process 800 determines that the pressure is greater than the third threshold, the process 800 may follow the “YES” route and proceed to 820. At 820, the process 800 may include causing a LCC to provide supplemental cooling via the radiator of the thermal management system. For example, coolant flowing through the radiator may cool the refrigerant flowing through the LCC. The valve(s), pump(s), junction(s), fittings, etc., of the thermal management system may be controlled to fluidly connect the radiator and the LCC. Moreover, in an embodiment, if the vehicle includes more than one radiator, the thermal management system may utilize a a radiator at a leading edge of the vehicle, for example.

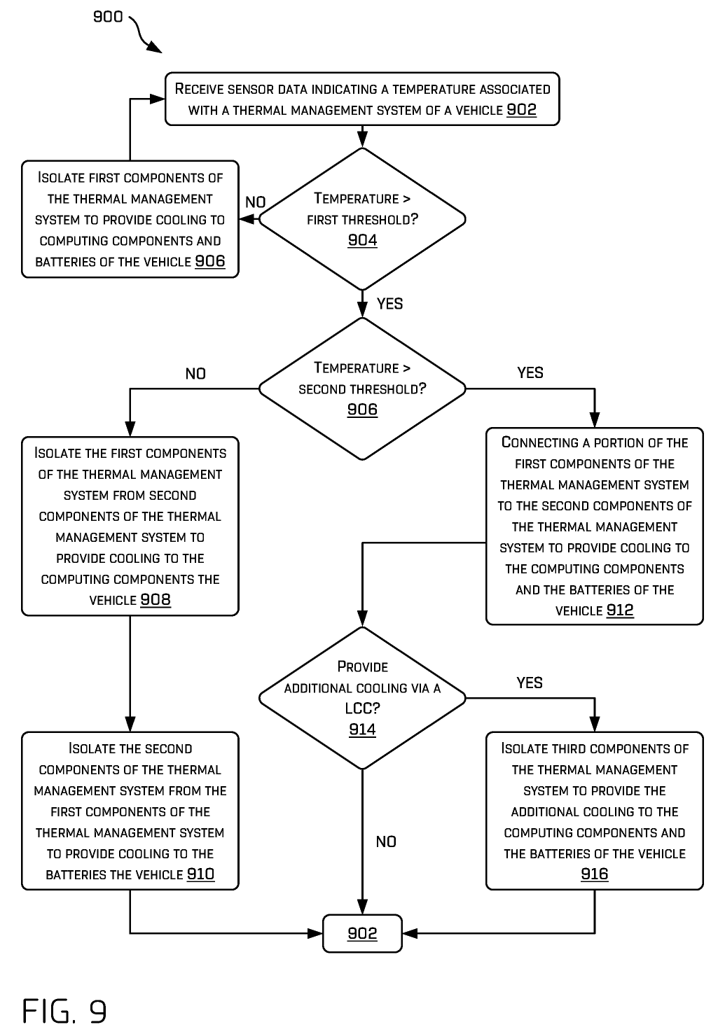

FIG. 9 illustrates an example process 900 associated with cooling computing components and/or batteries of a vehicle, according to an embodiment of the present disclosure. In an embodiment, the process 900 may be implemented at least in part by the vehicle computing device(s) 604.

At 902, the process 900 may include receiving sensor data indicating a temperature associated with a thermal management system of a vehicle. For example, sensor data may be generated from one or more sensor(s) of the vehicle, where the sensor data indicates a temperature of a coolant flowing through the thermal management system. In an embodiment, the temperature may be a temperature of coolant exiting a radiator of the thermal management system, a temperature of an environment of the vehicle, temperatures of the computing components, the batteries, etc.

At 904, the process 900 may include determining whether the temperature is greater than a first threshold. For example, the temperature (from 902) may be compared to a first temperature threshold. In an embodiment, the first temperature threshold may be 35°C, which is associated with a maximum operating temperature of the batteries. If at 904, the process 900 determines that the temperature is not greater than the first threshold, the process 900 may follow the “NO” route and proceed to 906.

At 906, the process 900 may include isolating first components of the thermal management system to provide cooling to computing component(s) and batteries of the vehicle. For example, the first components may include the radiator, and the radiator, the computing components, and the batteries may be isolated from other components of the thermal management system (e.g., chiller). The first components may also include valve(s), pump(s), junction(s), fittings, etc., that permit coolant flowing through the radiator to be routed to the computing component(s) and the batteries to provide cooling. From 906, the process 900 may proceed to 902.

Returning to 904, if the process 900 determines that the temperature is greater than the first threshold, the process 900 may follow the “YES” route and proceed to 906. At 906, the process 900 may include determining whether the temperature is greater than a second threshold. For example, the temperature (from 902) may be compared to a second temperature threshold. In an embodiment, the second temperature threshold may be 55°C, which is associated with a maximum operating temperature of the computing component(s). If at 906 the process 90 determines that the temperature is not greater than the second threshold, the process 900 may follow the “NO” route and proceed to 908.

At 908, the process 900 may include isolating the first components of the thermal management system from second components to provide cooling to the computing components of the vehicle. For example, the radiator may be isolated from the batteries. Isolating the radiator from the batteries may cause the radiator to provide cooling to the computing components.

At 910, the process 900 may include isolating second components of the thermal management system from the first components of the thermal management system to provide cooling to the batteries of the vehicles. For example, the second computing components may include a chiller that cools coolant provided to the batteries. In other words, the chiller may be fluidly isolated from the radiator. The second components may also include valve(s), pump(s), junction(s), fittings, etc., that permit coolant flowing through the chiller to be routed to the batteries. The chiller may be fluidly connected to a compressor, a condenser, and/or an LCC that cools a refrigerant, and within the chiller, the refrigerant may exchange heat with the coolant. Coolant routing through the radiator may cool the computing component(s), while coolant routing through the chiller may cool the batteries. From 910, the process 900 may proceed to 902.

Returning to 906, if the process 900 determines that the temperature is greater than the second threshold, the process 900 may follow the “YES” route and proceed to 912. At 912, the process 900 may include connecting a portion of the first components of the thermal management system to the second components of the thermal management to provide cooling to the computing components and the batteries of the vehicle. For example, valve(s), pump(s), junction(s), fittings, etc., that previously fluidly connected the radiator to the computing components may be used to route the coolant flowing through the chiller to the computing components. In other words, the chiller may be fluidly connected to the computing components, such that coolant cooled within the chiller may be routed to both the computing components and the batteries.

At 914, the process 900 may determine whether to provide additional cooling via a LCC of the thermal management system. Whether the LCC provides additional cooling may be based on a pressure of a refrigerant output of a compressor of the thermal management system. For example, sensor data may be received, whereby the sensor data may be associated with a pressure of the refrigerant exiting the compressor. In an embodiment, the pressure may be associated with an amount of work required by the compressor to cool the coolant to provide cooling to the computing component(s) and the batteries. In an embodiment, rather than measuring a pressure of the refrigerant exiting the compressor, the process 900 may determine a temperature of the coolant, the refrigerant, the computing component(s), the batteries, etc., for determining whether to provide additional cooling via the LCC.

If at 914, the process 900 determines to not provide additional cooling via the LCC, the process 900 may follow the “NO” route and proceed to 902. Alternatively, if at 914, the process 900 determines to provide additional cooling via the LCC, the process 900 may follow the “YES” route and proceed to 916. At 916, the process 900 may include isolating third components of the thermal management system to provide additional cooling to the computing components and the batteries of the vehicle. For example, the radiator may be fluidly connected to the LCC, whereby the refrigerant flowing through the chiller, the compressor, and the condenser may additionally be cooled via coolant flowing through the radiator. In an embodiment, some of the third components may include a portion of the first components (e.g., the radiator). The third components may also include valve(s), pump(s), junction(s), fittings, etc., that route the coolant from the radiator to the LCC. From 916, the process 900 may proceed to 902.

### Example Clauses

The following paragraphs describe various examples. Any of the examples in this section may be used with any other of the examples in this section and/or any of the other examples or embodiments described herein.
A: A vehicle comprising: one or more computing components that at least partially control an operation of the vehicle within an environment; one or more batteries that provide power to the vehicle; a sensor; a thermal management system that provides cooling to the one or more computing components and the one or more batteries, the thermal management system including: a radiator fluidly connected to the one or more computing components and the one or more batteries, and a chiller fluidly connected to the one or more computing components and the one or more batteries; one or more processors; and one or more non-transitory computer-readable media storing computer-executable instructions that, when executed by the one or more processors, cause the one or more processors to perform operations comprising: receiving, from the sensor, sensor data associated with a temperature of the one or more computing components or the one or more batteries, determining that the temperature is greater than a first temperature threshold, determining that the temperature is less than a second temperature threshold, the second temperature threshold being different than the first temperature threshold, and causing, based at least in part on the temperature being greater than the first temperature threshold and less than the second temperature threshold: the radiator to provide cooling to the one or more computing components, and the chiller to provide cooling to the one or more batteries.
B: The vehicle of paragraph A, the operations further comprising: receiving, from the sensor, second sensor data associated with a second temperature of the one or more computing components or the one or more batteries; determining that the second temperature is greater than the second temperature threshold; and causing, based at least in part on the second temperature being greater than the second temperature threshold, the chiller to provide cooling to the one or more computing components and the one or more batteries.
C: The vehicle of paragraph A or B, wherein a refrigerant flows through the chiller and a liquid cooled condenser (LCC), the operations further comprising: determining at least one of: an amount of cooling required by the chiller to provide the cooling to the one or more computing components and the one or more batteries, or a pressure of the refrigerant; and causing the LCC to provide cooling to the one or more computing components and the one or more batteries.
D: The vehicle of any of paragraphs A-C, wherein: causing the radiator to provide cooling to the one or more computing components comprises isolating a first portion of the thermal management system from a second portion of the thermal management system, the first portion of the thermal management system including the radiator and the second portion of the thermal management system including the chiller; and causing the chiller to provide cooling to the one or more computing components and the one or more batteries comprises connecting the first portion to the second portion to allow a flow of coolant from the first portion to the second portion.
E: A thermal management system for a vehicle comprising: a radiator configured to cool a coolant; a chiller configured to cool the coolant; one or more processors; and one or more non-transitory computer-readable media storing computer-executable instructions that, when executed by the one or more processors, cause the one or more processors to perform operations comprising: receiving data indicative of a temperature associated with the thermal management system, determining that the temperature is greater than a first temperature threshold, determining that the temperature is less than a second temperature threshold, and based at least in part on the temperature being greater than the first temperature threshold and less than the second temperature threshold, causing: a first portion of the coolant that is cooled via the radiator to cool one or more computing components of the vehicle, and a refrigerant flowing through the chiller to cool a second portion of the coolant, wherein the second portion of the coolant cools a battery of the vehicle.
F: The thermal management system of paragraph E, the operations further comprising: receiving second sensor data indicative of a second temperature associated with the thermal management system; determining that the second temperature is greater than the second temperature threshold; and based at least in part on the second temperature being greater than the second temperature threshold, causing the refrigerant flowing through the chiller to cool a third portion of the coolant, wherein: the third portion of the coolant represents a combination of the first portion of the coolant and the second portion of the coolant, and the third portion of the coolant cools the battery and the one or more computing components.
G: The thermal management system of paragraph E or F, wherein the chiller is fluidly connected to a liquid cooled condenser (LCC), the operations further comprising: receiving third sensor data associated with a pressure of the refrigerant; determining that the pressure is greater than a pressure threshold; and causing a fourth portion of the coolant flowing through the LCC to cool the refrigerant, wherein: the fourth portion of the coolant is cooled via the radiator, and the fourth portion of the coolant is isolated from the third portion of the coolant. H: The thermal management system of any of paragraphs E-G, wherein: the first temperature threshold is based at least in part on a maximum operating temperature of the battery; and the second temperature threshold is based at least in part on a maximum operating of the one or more computing components.
I: The thermal management system of any of paragraphs E-H, wherein one or more first valves supply the first portion of the coolant to the one or more computing components, and one or more second valves supply the second portion of the coolant to the battery, the operations further comprising: determining a first setting of the one or more first valves for supplying the first portion of the coolant to the one or more computing components; and determining a second setting of the one or more second valves for supplying the second portion of the coolant to the battery.
J: The thermal management system of any of paragraphs E-I, wherein: at least one valve of the one or more first valves is controllable to: isolate the first portion of the coolant and the second portion of the coolant, and combine the first portion of the coolant and the second portion of the coolant; and at least one valve of the one or more second valves is controllable to: isolate the first portion of the coolant and the second portion of the coolant, and combine of the first portion of the coolant and the second portion of the coolant.
K: The thermal management system of any of paragraphs E-J, wherein the temperature associated with the thermal management system comprises: a first temperature of the first portion of the coolant exiting the radiator; a second temperature of the one or more computing components; a third temperature of the battery; or a fourth temperature of an environment of the vehicle.
L: The thermal management system of any of paragraphs E-K, the operations further comprising: receiving second data indicative of a second temperature associated with the thermal management system; determining that the second temperature is less than the first temperature threshold; and based at least in part on the temperature being less than the first temperature threshold, causing: the first portion of the coolant to combine with at least part of the second portion of the coolant, and the first portion of the coolant and the at least part of the second portion of the coolant to cool the one or more computing components of the vehicle and the battery of the vehicle.
M: The thermal management system of any of paragraphs E-L, wherein the one or more computing components and the battery are cooled in parallel.
N: A thermal management system for a vehicle, comprising: a chiller; one or more processors; and one or more non-transitory computer-readable media storing computer-executable instructions that, when executed by the one or more processors, cause the one or more processors to perform operations comprising: determining a temperature associated with the thermal management system, determining that the temperature is greater than a first temperature threshold, determining that the temperature is greater than a second temperature threshold, and based at least in part on the temperature being greater than the second temperature threshold, causing: a first portion of a coolant flowing through the chiller to cool one or more computing components of the vehicle, and a second portion of the coolant flowing through the chiller to cool a battery of the vehicle.
O: The thermal management system of paragraph N, further comprising a liquid cooled condenser (LCC) fluidly connected to the chiller.
P: The thermal management system of paragraph N or O, further comprising a compressor fluidly connected to the chiller and the LCC, the operations further comprising: determining at least one of: a pressure of a refrigerant exiting the compressor, an amount of work performed by the compressor, or a temperature differential across the chiller; and causing the LCC to cool a refrigerant flowing through the LCC based at least in part on at least one of the pressure, the amount of work, or the temperature differential.
Q: The thermal management system of any of paragraphs N-P, wherein the one or more computing components and the battery are cooled in parallel.
R: The thermal management system of any of paragraphs N-Q, wherein the temperature is associated with: a first temperature of the first portion of the coolant; a second temperature of the second portion of the coolant; a third temperature of the battery; or a fourth temperature of the one or more computing components.
S: The thermal management system of any of paragraphs N-R, further comprising a radiator, the operations further comprising based at least in part temperature being greater than the second temperature threshold, the chiller and the battery to be fluidly isolated from the radiator.
T: The thermal management system of any of paragraphs N-S, the operations further comprising: determining a second temperature associated with the thermal management system; determining that the second temperature is less than the second temperature threshold; and based at least in part on the second temperature being less than the second temperature threshold, causing: the chiller to be fluidly isolated from the battery, the radiator to be fluidly connected to the battery, and the one or more computing components and the battery to be fluidly disconnected.

While the example clauses described above are described with respect to one particular implementation, it should be understood that, in the context of this document, the content of the example clauses may also be implemented via a method, device, system, computer-readable medium, and/or another implementation. Additionally, any of examples A-T may be implemented alone or in combination with any other one or more of the examples A-T.

### Conclusion

While one or more examples of the techniques described herein have been described, various alterations, additions, permutations and equivalents thereof are included within the scope of the techniques described herein.

In the description of examples, reference is made to the accompanying drawings that form a part hereof, which show by way of illustration specific examples of the claimed subject matter. It is to be understood that other examples may be used and that changes or alterations, such as structural changes, may be made. Such examples, changes or alterations are not necessarily departures from the scope with respect to the intended claimed subject matter. While the steps herein may be presented in a certain order, in some cases the ordering may be changed so that certain inputs are provided at different times or in a different order without changing the function of the systems and methods described. The disclosed procedures could also be executed in different orders. Additionally, various computations that are herein need not be performed in the order disclosed, and other examples using alternative orderings of the computations could be readily implemented. In addition to being reordered, the computations could also be decomposed into sub-computations with the same results.

What is claimed is:

1. A vehicle comprising:
one or more computing components that at least partially control an operation of the vehicle within an environment;
one or more batteries that provide power to the vehicle;
a sensor;
a thermal management system that provides cooling to the one or more computing components and the one or more batteries, the thermal management system including:
a radiator fluidly connected to the one or more computing components and the one or more batteries, and
a chiller fluidly connected to the one or more computing components and the one or more batteries;
one or more processors; and
one or more non-transitory computer-readable media storing computer-executable instructions that, when executed by the one or more processors, cause the one or more processors to perform operations comprising:
receiving, from the sensor, sensor data associated with a temperature of the one or more computing components or the one or more batteries,
determining that the temperature is greater than a first temperature threshold,
determining that the temperature is less than a second temperature threshold, the second temperature threshold being different than the first temperature threshold, and
causing, based at least in part on the temperature being greater than the first temperature threshold and less than the second temperature threshold:
the radiator to provide cooling to the one or more computing components, and
the chiller to provide cooling to the one or more batteries.

2. The vehicle of claim 1, the operations further comprising:
receiving, from the sensor, second sensor data associated with a second temperature of the one or more computing components or the one or more batteries;
determining that the second temperature is greater than the second temperature threshold; and
causing, based at least in part on the second temperature being greater than the second temperature threshold, the chiller to provide cooling to the one or more computing components and the one or more batteries.

3. The vehicle of claim 2, wherein a refrigerant flows through the chiller and a liquid cooled condenser (LCC), the operations further comprising:
determining at least one of:
an amount of cooling required by the chiller to provide the cooling to the one or more computing components and the one or more batteries, or
a pressure of the refrigerant; and
causing the LCC to provide cooling to the one or more computing components and the one or more batteries.

4. The vehicle of claim 2, wherein:
causing the radiator to provide cooling to the one or more computing components comprises isolating a first portion of the thermal management system from a second portion of the thermal management system, the first portion of the thermal management system including the radiator and the second portion of the thermal management system including the chiller; and
causing the chiller to provide cooling to the one or more computing components and the one or more batteries comprises connecting the first portion to the second portion to allow a flow of coolant from the first portion to the second portion.

5. A thermal management system for a vehicle comprising:
a radiator configured to cool a coolant;
a chiller configured to cool the coolant;
one or more processors; and
one or more non-transitory computer-readable media storing computer-executable instructions that, when executed by the one or more processors, cause the one or more processors to perform operations comprising:
receiving data indicative of a temperature associated with the thermal management system,
determining that the temperature is greater than a first temperature threshold,
determining that the temperature is less than a second temperature threshold, and
based at least in part on the temperature being greater than the first temperature threshold and less than the second temperature threshold, causing:
a first portion of the coolant that is cooled via the radiator to cool one or more computing components of the vehicle, and
a refrigerant flowing through the chiller to cool a second portion of the coolant, wherein the second portion of the coolant cools a battery of the vehicle.

6. The thermal management system of claim 5, the operations further comprising:
receiving second sensor data indicative of a second temperature associated with the thermal management system;
determining that the second temperature is greater than the second temperature threshold; and
based at least in part on the second temperature being greater than the second temperature threshold, causing the refrigerant flowing through the chiller to cool a third portion of the coolant, wherein:
the third portion of the coolant represents a combination of the first portion of the coolant and the second portion of the coolant, and
the third portion of the coolant cools the battery and the one or more computing components.

7. The thermal management system of claim 6, wherein the chiller is fluidly connected to a liquid cooled condenser (LCC), the operations further comprising:
receiving third sensor data associated with a pressure of the refrigerant;
determining that the pressure is greater than a pressure threshold; and
causing a fourth portion of the coolant flowing through the LCC to cool the refrigerant, wherein:
the fourth portion of the coolant is cooled via the radiator, and
the fourth portion of the coolant is isolated from the third portion of the coolant.

8. The thermal management system of claim 5, wherein:
the first temperature threshold is based at least in part on a maximum operating temperature of the battery; and
the second temperature threshold is based at least in part on a maximum operating of the one or more computing components.

9. The thermal management system of claim 5, wherein one or more first valves supply the first portion of the coolant to the one or more computing components, and one or more second valves supply the second portion of the coolant to the battery, the operations further comprising:
determining a first setting of the one or more first valves for supplying the first portion of the coolant to the one or more computing components; and
determining a second setting of the one or more second valves for supplying the second portion of the coolant to the battery.

10. The thermal management system of claim 9, wherein:
at least one valve of the one or more first valves is controllable to:
isolate the first portion of the coolant and the second portion of the coolant, and
combine the first portion of the coolant and the second portion of the coolant; and
at least one valve of the one or more second valves is controllable to:
isolate the first portion of the coolant and the second portion of the coolant, and
combine of the first portion of the coolant and the second portion of the coolant.

11. The thermal management system of claim 5, wherein the temperature associated with the thermal management system comprises:
a first temperature of the first portion of the coolant exiting the radiator;
a second temperature of the one or more computing components;
a third temperature of the battery; or
a fourth temperature of an environment of the vehicle.

12. The thermal management system of claim 5, the operations further comprising:
receiving second data indicative of a second temperature associated with the thermal management system;
determining that the second temperature is less than the first temperature threshold; and
based at least in part on the temperature being less than the first temperature threshold, causing:
the first portion of the coolant to combine with at least part of the second portion of the coolant, and
the first portion of the coolant and the at least part of the second portion of the coolant to cool the one or more computing components of the vehicle and the battery of the vehicle.

13. The thermal management system of claim 12, wherein the one or more computing components and the battery are cooled in parallel.

14. A thermal management system for a vehicle, comprising:
a chiller;
one or more processors; and
one or more non-transitory computer-readable media storing computer-executable instructions that, when executed by the one or more processors, cause the one or more processors to perform operations comprising:
determining a temperature associated with the thermal management system,
determining that the temperature is greater than a first temperature threshold,
determining that the temperature is greater than a second temperature threshold, and
based at least in part on the temperature being greater than the second temperature threshold, causing:
a first portion of a coolant flowing through the chiller to cool one or more computing components of the vehicle, and
a second portion of the coolant flowing through the chiller to cool a battery of the vehicle.

15. The thermal management system of claim 14, further comprising a liquid cooled condenser (LCC) fluidly connected to the chiller.

16. The thermal management system of claim 15, further comprising a compressor fluidly connected to the chiller and the LCC, the operations further comprising:
determining at least one of:
a pressure of a refrigerant exiting the compressor,
an amount of work performed by the compressor, or
a temperature differential across the chiller; and
causing the LCC to cool a refrigerant flowing through the LCC based at least in part on at least one of the pressure, the amount of work, or the temperature differential.

17. The thermal management system of claim 14, wherein the one or more computing components and the battery are cooled in parallel.

18. The thermal management system of claim 14, wherein the temperature is associated with:
a first temperature of the first portion of the coolant;
a second temperature of the second portion of the coolant;
a third temperature of the battery; or
a fourth temperature of the one or more computing components.

19. The thermal management system of claim 14, further comprising a radiator, the operations further comprising based at least in part temperature being greater than the second temperature threshold, the chiller and the battery to be fluidly isolated from the radiator.

20. The thermal management system of claim 19, the operations further comprising:
determining a second temperature associated with the thermal management system;
determining that the second temperature is less than the second temperature threshold; and
based at least in part on the second temperature being less than the second temperature threshold, causing:
the chiller to be fluidly isolated from the battery,
the radiator to be fluidly connected to the battery, and
the one or more computing components and the battery to be fluidly disconnected.
